(19) United States
(12) Patent Application Publication
(10) Pub. No.: US 2026/0235866 A1
(43) Pub. Date: Aug. 13, 2026

(54) OPTICAL SYSTEM FOR A PROJECTION EXPOSURE APPARATUS, AND METHOD FOR SPECIFYING AN ILLUMINATION PUPIL

(71) Applicant: Carl Zeiss SMT GmbH, Oberkochen (DE)

(72) Inventors: Alexander Winkler, Heidenheim (DE); Joerg Zimmermann, Aalen (DE); Martin Endres, Koenigsbronn (DE); Michael Ramolla, Oberkochen (DE); Jens Timo Neumann, Aalen (DE)

(21) Appl. No.: 19/633,309

(22) Filed: Mar. 30, 2026

Related U.S. Application Data
(63) Continuation of application No. PCT/EP2024/075913, filed on Sep. 17, 2024.

(30) Foreign Application Priority Data
Oct. 4, 2023 (DE) 102023209698.6

(51) Int. Cl. G02B 27/00; G03F 7/00

(52) U.S. Cl. CPC G02B 27/0081; G03F 7/70116; G03F 7/70141; G03F 7/7025; G03F 7/70516; G03F 7/7085

(57) ABSTRACT

An optical system for a projection exposure apparatus has an illumination optical unit for guiding illumination and imaging light from a light source to an object field, in which an object to be imaged is arrangeable, and an imaging optical unit for imaging the object field into an image field, in which a substrate to be exposed is arrangeable. The imaging optical unit has an exit pupil having at least one obscuration exit pupil region located within an outer pupil edge. The illumination optical unit is embodied in such a way that an illumination angle distribution of an illumination of the object field using the illumination and imaging light arises and is describable by way of an illumination pupil, the illumination pupil region of which impinged upon by illumination light being adapted to the obscuration exit pupil region of the imaging optical unit. The obscuration exit pupil region of the imaging optical unit can have a non-centric geometric centroid. In a variant of the optical system, the illumination optical unit is embodied in such a way that an illumination angle distribution arises in the object field and is describable by way of an illumination pupil with an obscuration illumination pupil region, the envelope of which, in pupil coordinates (σₓ, σ_{y}) normalized with respect to the outer pupil edge and/or in absolute pupil coordinates (ρₓ, ρ_{y}), deviates from a circular shape. To specify the illumination pupil, a diffraction behaviour of at least one object structure of the object to be imaged is analyzed, a position of the obscuration exit pupil region in the exit pupil is detected, and the illumination pupil is adapted such that at least one of the variants of the optical system arises. This results in an optical system with an improved resolution.

### CROSS-REFERENCE TO RELATED APPLICATIONS

This application is a continuation of and claims benefit under 35 U.S.C. § 120 from PCT Application PCT/EP2024/075913, filed on Sep. 17, 2024, which claims priority from German Application DE 10 2023 209 698.6, filed on Oct. 4, 2023. The entire contents of each of these earlier applications are incorporated herein by reference.

### TECHNICAL FIELD

The invention relates to an optical system for a projection exposure apparatus. Furthermore, the invention relates to a projection exposure apparatus having such an optical system, to a method for specifying an illumination pupil of an illumination optical unit with an adapted illumination pupil such that such an optical system arises, to a method for producing a microstructured or nanostructured component with the aid of such a projection exposure apparatus, and to a microstructured or nanostructured component produced according to the method.

### BACKGROUND

An optical system of the type set forth at the outset is known from WO 2012/028303 A1, U.S. Pat. No. 10,139,734 B2, U.S. Pat. No. 10,254,653 B2, DE 10 2021 200 114 A1, and U.S. Pat. No. 9,720,329 B2. Details of imaging optical units that might be suitable for use in lithographic projection exposure apparatuses are known from the journal article “Lithographic pattern formation in the presence of aberrations in anamorphic optical systems” by Levinson et al., Proc. of SPIE Vol. 11323 1132230A-1, 2020, the journal article “Extreme ultraviolet scanner with high numerical aperture: obscuration and wavefront description” by de Winter et al., J. Micro/Nanopattern. Mater. Metrol. 023801-2, 2022, the journal article “High NA EUV scanner: obscuration and wavefront description” by de Winter et al., Proc. of SPIE Vol. 11517 1151715-1, 2020, the journal article “High NA EUV lithography: Next step in EUV imaging” by van Setten et al., Proc. of SPIE Vol. 10957 1095709-01, 2019, the journal article “Physical dose modeling and throughput optimization in EUV computational lithography” by Peng et al., Proc. of SPIE Vol. 12494 124940C-1, 2023, the journal article “Defining Tatian-Zernike polynomials for use in a lithography simulator” by Maguire et al., Proc. of SPIE Vol. 12494 124940P-1, 2023, the journal article “Computational lithography solutions to support EUV high-NA patterning” by Zhao et al., Proc. of SPIE Vol. 12495 124950R-1, 2023, the journal article “High-NA EUV lithography exposure tool: program progress” by van Schoot et al., Proc. of SPIE Vol. 11323 1132307-1, 2023, the journal article “High-NA EUV lithography optics becomes reality” by Wischmeier et al., Proc. of SPIE Vol. 11323 1132308-1, 2020, the journal article “High-NA EUV lithography exposure tool: advantages and program progress” by van Schoot et al., Proc. of SPIE Vol. 11517 1151712-1, 2020, and the journal article “Computational evaluation of critical logical metal layers of pitch 20-24 nm and the aberration sensitivity in high NA EUV single patterning” by Gao et al., Proc. of SPIE Vol. 12495 1249509-1, 2023.

### SUMMARY

The problem addressed by the present invention is that of improving a resolution of an optical system of the type set forth at the outset.

According to the invention, this problem is solved by an optical system having the features specified in claim 1 and by an optical system having the features specified in claim 2.

According to the invention, it was recognized that an adaptation of an illumination pupil of the illumination optical unit in the optical system to an exit pupil of the imaging optical unit in the optical system provides the possibility of further improving an imaging behavior of the optical system and hence of improving the resolution thereof. Accordingly, this gives rise to the possibility of using the projection exposure apparatus to image the respective object to be imaged onto a substrate, in particular in the form of a wafer, with improved resolution.

In particular, it has transpired that the adaptation of the illumination pupil to an obscuration exit pupil region of the imaging optical unit is particularly useful. As a result of adapting the illumination pupil to the obscuration exit pupil region, the illumination light is provided where it can be used effectively for high-resolution imaging.

In particular, an obscuration illumination pupil region with a non-centric geometric centroid, i.e., an obscuration illumination pupil region having a balance point which is not located at the center of the exit pupil, can also be provided in this context.

The illumination pupil can comprise at least one illumination pole. The illumination pupil can comprise at least two illumination poles. The illumination pupil can comprise exactly one, exactly two, exactly three, exactly four, exactly five, exactly six, exactly seven, exactly eight, exactly nine or else exactly ten illumination poles. A greater number of illumination poles within the illumination pupil is also possible.

An illumination pole is an illumination-pupil pupil region which is describably delimited by way of an envelope and illuminated by the illumination light. Overall, the illumination pole can be illuminated without gaps by the illumination light, or a distribution of incidence locations of illumination channels specified by way of the illumination optical unit can be present within the illumination pole.

Corresponding advantages are particularly effective in the case of adaptation to an obscuration exit pupil region with a non-centric geometric centroid according to claim 1. The adaptation is implemented by way of a corresponding specification of the illumination pupil, with consideration being given in particular to those illumination pupil regions which interact with the obscuration exit pupil region of the imaging optical unit. In this case, consideration can be given in particular to a diffraction of the illumination pupil at structures of the object to be imaged.

An obscuration illumination pupil region according to claim 2 provides additional degrees of freedom when adapting the illumination pupil to an obscured exit pupil of the imaging optical unit.

The exit pupil to be adapted may have an outer boundary and/or a boundary of the obscuration exit pupil region which has a circular shape in normalized and/or absolute pupil coordinates or which else alternatively deviates from a circular shape and, for example, has an elliptical shape.

Accordingly, the illumination pupil adapted thereto can also have an outer boundary and/or a boundary of an obscuration illumination pupil region which has a circular shape in normalized and/or absolute pupil coordinates or which else alternatively deviates from a circular shape and, for example, has an elliptical shape. Especially in the case of an anamorphic imaging optical unit, an obscuration exit pupil region of the imaging optical unit can have a circular shape, whereas an obscuration illumination pupil region has an envelope that deviates from a circular shape.

An illumination pupil according to claim 3 takes account of the obscuration exit pupil region such that zeroth-order illumination light is not unnecessarily blocked at an obscuration of the imaging optical unit. This results in a correspondingly increased light throughput.

An illumination pupil according to claim 4 takes account of the fact that diffracted imaging light within the exit pupil is not undesirably diffracted into the obscuration exit pupil region. In this case, consideration can be given to a corresponding diffraction direction, depending on an alignment of object structures to be imaged. A plurality of diffraction directions can also be considered when designing the illumination pupil that is adapted to the exit pupil.

In the case of an illumination pupil according to claim 5, there is, in any case regionally, an illumination of the illumination pupil adjacent to an obscuration illumination pupil region that is adapted to an obscuration exit pupil region. In that case, illumination pupils with a high integrated light throughput can be provided. Diffraction effects in at least one diffraction direction can also be taken into account when specifying such illumination pupils. For example, the illumination pupil can be specified in such a way that diffracted illumination light is not undesirably blocked at the obscuration exit pupil region.

In any case, an illumination pupil according to claim 6 can provide a component of dark field illumination in which illumination light of the zeroth order of diffraction does not reach the image field but is blocked at an obscuration and/or at an outer edge of the exit pupil. In addition to such a dark field illumination component, the illumination pupil can also provide further illumination components in which illumination light of the zeroth order of diffraction also reaches the image field.

A swamped obscuration illumination which also contains an illumination component in an illumination pupil region in which imaging light of the zeroth order of diffraction reaches the image field in addition to the dark field illumination can be provided by use of an illumination pupil according to claim 7.

An illumination pupil with an illumination pupil surround not impinged upon by illumination light, according to claim 8, yields an illumination pupil which takes account of tolerances of a pose of the obscuration exit pupil region, in particular drift tolerances or else field-dependence tolerances. Slight pupil displacements do not lead to an illumination pupil region located within an obscuration exit pupil region prior to the displacement undesirably emerging therefrom, and vice versa. It is possible to take account of tolerances of the imaging optical unit, in particular tolerances in the obscuration exit pupil region, and tolerances of the illumination optical unit, in particular tolerances in the obscuration illumination pupil region. In general, it is possible to take account of tolerances in the illumination light guidance, i.e., of an illumination light beam path, and tolerances of an imaging beam path.

An extent of the illumination pupil surround along a coordinate perpendicular to a respective edge section of the edge of the obscuration exit pupil region, i.e., a distance between regions of the adapted illumination pupil impinged upon by the illumination light, can be in the range between 0.1% and 5% of an entire pupil extent.

Overall, a dark field illumination can be provided by using an illumination pupil according to claim 9; this offers particular resolution advantages for certain imaging tasks.

By use of an adapted illumination pupil according to claim 10, it is possible to take account of diffraction effects and/or field-dependency effects of the exit pupil, especially if the illumination pupil itself does not have a field-dependent embodiment.

A field-dependent illumination pupil according to claim 11 offers particular advantages in terms of flexibility. The field dependence of the illumination pupil can be used to ensure an adaptation of a correspondingly field-dependent exit pupil. However, as an alternative to that or in addition, the field dependence of the illumination pupil can also be used for adaptation to a field-dependently varying diffraction behavior of structures of the object to be imaged.

Corresponding advantages are provided by the illumination pupil according to claim 12.

Edge contour parameters according to claim 13 yield a particularly effective adaptation of the illumination pupil. The decentration of the edge contour of the obscuration exit pupil region can be in the range between 0.004 and 0.02, between 0.005 and 0.01 and, for example, between 0.006 and 0.007. A mean deviation of the edge contour of the obscuration exit pupil region from a circular shape can be in the range between 0.125 and 0.275, in particular between 0.15 and 0.275.

The illumination optical unit can be equipped with a field facet mirror and a pupil facet mirror according to claim 14; this has proven its worth in practice. Alternatively, the illumination optical unit may, for example, comprise a field facet mirror and a further facet mirror arranged at a distance from a pupil plane of the illumination optical unit. Such a concept is known in the prior art as a specular reflector.

The illumination optical unit according to claim 15 can be equipped with facet mirrors which provide a plurality of groups of individual transfer mirrors and/or groups of individual illumination specification mirrors, for the purpose of specifying the respective illumination channels. Such facet mirrors can be in the form of MEMS mirrors.

The light source of the optical system according to claim 16 can be an EUV light source or else a DUV light source. EUV illumination light can have a wavelength in the range between 5 nm and 30 nm, for example, of the order of 13.5 nm. DUV illumination light can have a wavelength of 193 nm or else a longer wavelength.

The advantages of a projection exposure apparatus according to claim 19 correspond to those which have already been explained above with reference to the optical system according to the invention.

A further problem addressed by the present invention is that of specifying an illumination pupil adaptation method which enables an improvement of an optical system resolution.

According to the invention, this problem is solved by a specification method having the method steps stated in claim 20.

In the specification method, consideration is given both to an object diffraction behavior and a function of an obscuration exit pupil region. This results in a correspondingly optimized illumination.

The method according to claim 21 gives consideration to a field dependence of an exit pupil of the imaging optical unit and/or a field dependence of an object diffraction, which can lead to additional resolution advantages for the illumination and/or to illumination/imaging light throughput advantages within the optical system.

The advantages of a production method according to claim 22 and of a microstructured or nanostructured component according to claim 23 corresponds to those which have already been explained above with reference to the illumination optical unit. The component produced may be a semiconductor element, especially a microchip, in particular a memory chip.

### BRIEF DESCRIPTION OF DRAWINGS

Exemplary embodiments of the invention are explained in greater detail below with reference to the drawing, in which:

FIG. 1 shows very schematically, in meridional section, a projection exposure apparatus for EUV microlithography, having a light source, an illumination optical unit and a projection optical unit, wherein a plan view of an object field of the projection exposure apparatus is depicted in an insert;

FIG. 2 shows schematically and likewise in meridional section a beam path of selected individual rays of illumination light within the illumination optical unit according to FIG. 1, proceeding from an intermediate focus through to a reticle or object arranged in the object plane of the projection optical unit in the region of the illumination or object field;

FIG. 3 shows a plan view of a first facet mirror of the illumination optical unit, which is arranged in a field plane of the illumination optical unit and in an illumination far field of the light source and which is also referred to as a field facet mirror, wherein an array arrangement of individual mirror units, in each case formed from a sub-array, not visible in FIG. 1, of individual mirrors of the first facet mirror, is depicted;

FIG. 4 shows, still schematically but in comparison with FIG. 3 in an enlarged, exemplary and more detailed manner, one of the individual mirror units embodied as a sub-array of the individual mirrors;

FIG. 5 shows a plan view of an illumination specification facet mirror of the illumination optical unit, said mirror being arranged at a distance from a pupil plane of the illumination optical unit and also being referred to as second facet mirror;

FIG. 6 shows, once again schematically, an embodiment of the illumination optical unit of the projection exposure apparatus, having two facet mirrors, which are embodied as MEMS mirrors with a multiplicity of individual mirrors, wherein the second facet mirror once again serving as an illumination specification facet mirror is arranged at a distance from a pupil plane of the illumination optical unit, and wherein, by way of example, two illumination channels of the illumination optical unit for the superimposed illumination of the reticle with a defined illumination angle distribution are highlighted, and wherein, additionally, selected individual rays for illuminating the object field from three different directions (two pupil marginal rays and a chief ray) are elucidated;

FIG. 7 shows an obscuration illumination pupil region of an illumination pupil of the illumination optical unit adapted to an obscuration exit pupil region of the projection optical unit of the projection exposure apparatus, wherein this illustrates an illumination of the illumination pupil within the obscuration illumination pupil region by way of illumination light and via a plurality of illumination channels indicated in FIG. 7 by way of corresponding illumination light intensity isolines;

FIG. 8 shows, in an illustration similar to FIG. 7, an embodiment of an adapted illumination pupil of the illumination optical unit having an inner obscuration illumination pupil region, which in turn is adapted to an obscuration exit pupil region of the projection optical unit, and an outer illumination pupil region surrounding this obscuration illumination pupil region, wherein an illumination pupil surround situated between the obscuration illumination pupil region and the outer illumination pupil region and including an assigned region of the exit pupil of the projection optical unit adjacent to an edge of an obscuration exit pupil region, once again elucidated by way of individual illumination channels, is not impinged upon by illumination light;

FIGS. 9A/9B schematically show two variants of an adapted illumination pupil with a dark field illumination, i.e., in the case of which illumination light is radiated at the reticle from angles not located within an exit pupil of the projection optical unit;

FIGS. 10 to 12 show embodiments of an adapted illumination pupil, in the case of which an obscuration illumination pupil region, which corresponds to an obscuration exit pupil region of the projection optical unit, is not impinged upon by illumination light;

FIG. 13 shows an illumination pupil, in the case of which an obscuration illumination pupil region, which is adapted to the obscuration exit pupil region of the imaging optical unit, is illuminated completely such that this results in a dark field illumination in accordance with FIG. 9A;

FIG. 14 shows, in an illustration similar to FIG. 13, an adapted illumination optical unit, in the case of which the illumination pupil is additionally not impinged upon by illumination light in an illumination pupil coordinate range of a cross diffraction pupil coordinate perpendicular to a diffraction pupil coordinate, the illumination pupil coordinate range corresponding to the extent of the obscuration exit pupil region along this cross diffraction pupil coordinate, but the said illumination pupil is impinged upon beyond this illumination pupil coordinate range of the cross diffraction pupil coordinate in four illumination pupil regions of the illumination pupil outside of the obscuration illumination pupil region;

FIG. 15 shows, in an illustration similar to FIG. 13, an embodiment of the adapted illumination pupil with a completely swamped obscuration illumination pupil region;

FIG. 16 shows, in an illustration similar to FIG. 15, an adapted illumination pupil, the illumination pupil region of which, in a manner similar to FIG. 8, is not impinged upon by illumination light in an illumination pupil surround which corresponds to a region of the exit pupil adjacent to an edge of the obscuration exit pupil region;

FIG. 17 shows, in an illustration similar to FIGS. 10 to 16, an embodiment of an obscuration illumination pupil region of an adapted illumination pupil, wherein the obscuration illumination pupil region is impinged upon by illumination light in such a way that there is no illumination in the obscuration illumination pupil region where, in the exit pupil, a section of a diffraction pupil region arises outside of the exit pupil;

FIG. 18 shows, in an illustration similar to FIG. 17, a variant of an illumination of the obscuration illumination pupil region, in such a way that there is no illumination within the obscuration illumination pupil region where this results in an overlap with diffraction pupil regions in the exit pupil;

FIGS. 19 to 21 show an adapted dark field illumination pupil similar to that according to FIG. 13, albeit with an outer envelope of the obscuration illumination pupil region that deviates from an ellipse, wherein the dark field illumination pupil is depicted for three different field heights, specifically at a smallest field height coordinate (FIG. 19), at a central field height coordinate (FIG. 20) and at a greatest field height coordinate (FIG. 21), wherein an illumination field dependence of the dark field illumination pupil follows an exit pupil field dependence of an exit pupil;

FIGS. 22 to 24 show, in illustrations similar to FIGS. 19 to 21, an obscuration illumination pupil region, located within an obscuration exit pupil region, of a further embodiment of an illumination pupil region adapted to the obscuration exit pupil region, wherein in this case an illumination angle distribution of the adapted illumination pupil is not field-dependent, but an exit pupil of the projection optical unit is field-dependent;

FIG. 25 shows, in an illustration similar to FIG. 13, an embodiment of an adapted illumination pupil, set as a distribution of illumination channels by way of an illumination optical unit, in which the first facet mirror is embodied as a field facet mirror and the second facet mirror is embodied as a pupil facet mirror, depicted in normalized pupil coordinates which represent a measure for a maximum illumination angle in the radial direction possible within the pupil in each case;

FIG. 26 shows the illumination pupil according to FIG. 25, depicted in absolute, non-normalized pupil coordinates which represent a measure for the actual illumination angle;

FIG. 27 shows, in an illustration similar to FIG. 25, an adapted illumination pupil according to that of FIG. 11 with a centred obscuration illumination pupil region, once again set by way of the illumination optical unit with the field facet mirror and the pupil facet mirror;

FIG. 28 shows the illumination pupil according to FIG. 27 in an absolute pupil coordinate representation corresponding to FIG. 26;

FIG. 29 shows, in an illustration corresponding to FIG. 25, an embodiment of an adapted illumination pupil with an obscuration illumination pupil region which is not impinged upon by illumination light and which is adapted to the obscuration exit pupil region, wherein the illumination pupil is only illuminated in a pupil region adjacent to the edge of the obscuration exit pupil region;

FIG. 30 shows the illumination pupil according to FIG. 29 in an absolute pupil coordinate representation corresponding to FIG. 26;

FIG. 31 shows, in an illustration similar to FIG. 25, an adapted illumination pupil in the style of that in FIG. 16, once again set by way of the illumination optical unit with the field facet mirror and the pupil facet mirror;

FIG. 32 shows the illumination pupil according to FIG. 31 in an absolute pupil coordinate representation corresponding to FIG. 26;

FIG. 33 shows, in an illustration similar to FIG. 25, an embodiment of an adapted illumination pupil which represents a superimposition of the pupil according to FIG. 25 with an x-dipole illumination pupil with two pupil strips fully illuminated over the pupil along the cross diffraction pupil coordinate;

FIG. 34 shows the illumination pupil according to FIG. 33 in an absolute pupil coordinate representation corresponding to FIG. 26;

FIG. 35 shows an embodiment of the illumination pupil according to FIG. 14, set by way of the illumination optical unit having the field facet mirror and the pupil facet mirror;

FIG. 36 shows the illumination pupil according to FIG. 35 in an absolute pupil coordinate representation corresponding to FIG. 26;

FIG. 37 shows, in an illustration similar to FIG. 35, an embodiment of an adapted illumination pupil, once again with an illuminated obscuration illumination pupil region corresponding to an obscuration exit pupil region, and with further illumination pupil regions in the form of four illumination poles, wherein the illumination pupil is not impinged upon by illumination light in an illumination pupil coordinate range along the diffraction pupil coordinate, wherein this illumination pupil coordinate range not impinged upon corresponds to the extent of the obscuration exit pupil region along the diffraction pupil coordinate according to FIG. 14;

FIG. 38 shows the illumination pupil according to FIG. 37 in an absolute pupil coordinate representation corresponding to FIG. 26;

FIG. 39 shows, in an illustration similar to FIGS. 33 to 38, a further embodiment of an adapted illumination pupil, settable by way of the illumination optical unit having the field facet mirror and the pupil facet mirror, wherein this illumination pupil represents a superimposition of an illuminated obscuration illumination pupil region, corresponding to obscuration exit pupil region, with a quadrupole illumination pupil;

FIG. 40 shows the illumination pupil according to FIG. 39 in an absolute pupil coordinate representation corresponding to FIG. 26;

FIG. 41 shows, in an illustration similar to FIG. 39, an adapted illumination pupil with once again an illuminated obscuration illumination pupil region adapted to an obscuration exit pupil region of the projection optical unit, having a total of eight mutually separated, illuminated illumination pupil regions in the form of illumination poles outside of the obscuration illumination pupil region;

FIG. 42 shows the illumination pupil according to FIG. 41 in an absolute pupil coordinate representation corresponding to FIG. 26;

FIG. 43 shows an adapted target illumination pupil in the style of FIG. 29 with a stadium-shaped obscuration illumination pupil region and homogeneous illumination between an inner and an outer boundary;

FIG. 44 shows an actual illumination pupil corresponding to FIG. 43, set by way of a specular reflector design of the illumination optical unit according to FIG. 6;

FIG. 45 schematically shows, in a plan view, an embodiment of a reticle to be illuminated, with regions of fine reticle structures and regions of coarse reticle structures;

FIG. 46 shows an embodiment of an adapted illumination pupil corresponding to that according to FIG. 10 for the finer reticle structures of the reticle according to FIG. 45;

FIG. 47 shows, in an illustration similar to FIG. 46, an embodiment of the adapted illumination pupil for the coarser reticle structures according to FIG. 45 and for reticle structure transition regions between the finer and the coarser reticle structures;

FIG. 48 shows a total of four variants of an edge contour of an adapted obscuration illumination pupil region, which is adapted to a given shape of an obscuration exit pupil region of the projection optical unit; and

FIG. 49 in turn shows, in an illustration similar to FIG. 48, four variants of an edge contour of an adapted obscuration illumination pupil region, which is adapted to a further variant of a shape of an obscuration exit pupil region of the projection optical unit.

### DETAILED DESCRIPTION

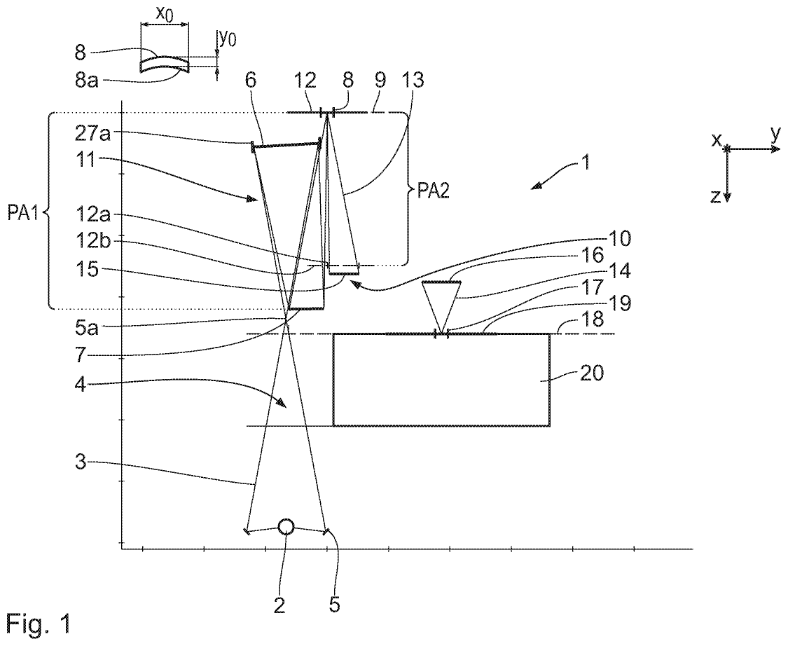

A microlithographic projection exposure apparatus 1 that is illustrated highly schematically and in meridional section in FIG. 1 has a light source 2 for illumination and imaging light 3. The light source 2 is an EUV light source which creates light in a wavelength range between 5 nm and 30 nm. Here, this may be an LPP (laser produced plasma) light source, a DPP (discharge produced plasma) light source or a synchrotron radiation-based light source, for example, a free electron laser (FEL).

For guiding the illumination light 3, proceeding from the light source 2, use is made of a transfer optical unit 4. The latter has a collector 5, which is illustrated only with regard to its reflective effect in FIG. 1, and a transfer facet mirror 6, which is described in even greater detail below and which is also denoted as first facet mirror or as field facet mirror. An intermediate focus 5a of the illumination light 3 is arranged between the collector 5 and the transfer facet mirror 6. A numerical aperture of the illumination light 3 in the region of the intermediate focus 5a is NA=0.182, for example. An illumination specification facet mirror 7, which is also denoted as second or further facet mirror and is likewise explained in even greater detail below, is disposed downstream of the transfer facet mirror 6 and thus the transfer optical unit 4. The optical components 5 to 7 are parts of an illumination optical unit 11 of the projection exposure apparatus 1.

In an embodiment of the illumination optical unit 11, the transfer facet mirror 6 is arranged in a field plane of the illumination optical unit 11. The first facet mirror 6 is embodied for arrangement in a used region of a far field of the light source 2.

In one embodiment of the illumination optical unit 11, the illumination specification facet mirror 7 of the illumination optical unit 11 is arranged at a distance from pupil planes of the illumination optical unit 11. Such an arrangement is also denoted as specular reflector. Alternatively, the illumination specification facet mirror 7 can also be arranged in the region of a pupil plane of the illumination optical unit 11, and it is denoted as a pupil facet mirror in that case.

A reticle 12 is disposed downstream of the illumination specification facet mirror 7 in the beam path of the illumination light 3, said reticle being arranged in an object plane 9 of a downstream projection optical unit 10 of the projection exposure apparatus 1. The projection optical unit 10 is a projection lens. The projection optical unit 10 is also referred to hereinbelow as imaging optical unit.

The illumination optical unit 11 is used to illuminate an object field 8 on the reticle 12 in the object plane 9 in a defined manner. The object field 8 simultaneously constitutes an illumination field of the illumination optical unit 11. Generally it holds true that the illumination field is formed in such a way that the object field 8 may be arranged in the illumination field.

Like the transfer facet mirror 6 as well, the illumination specification facet mirror 7 is part of a pupil illumination unit of the illumination optical unit and serves to illuminate an entrance pupil 12a in a pupil plane 12b of the projection optical unit 10 with the illumination light 3 with a specified pupil intensity distribution. The entrance pupil 12a simultaneously constitutes an illumination pupil of the illumination optical unit 11. The entrance pupil 12a of the projection optical unit 10 may be arranged in the illumination beam path upstream of the object field 8 or else downstream of the object field 8.

In the embodiment according to FIG. 1, the illumination optical unit 11 has exactly two mirrors that guide the illumination light 3 downstream of the collector 5, specifically the two facet mirrors 6 and 7. Depending on the embodiment of the illumination optical unit 11, these two mirrors 6, 7 can also be complemented by further mirrors for guiding the illumination light 3 between the collector 5 and the object field 8, for example, at least one deflection mirror between the collector 5 and the first facet mirror 6 and/or at least one deflection mirror between the two facet mirrors 6 and 7 and/or at least one deflection mirror between the second facet mirror 7 and the object field 8.

FIG. 1 shows the case in which the entrance pupil 12a is arranged in the illumination beam path downstream of the object field 8. A pupil distance PA between the second facet mirror 7 and the pupil plane 12b results in this case as the sum of a z-distance PA1 between the second facet mirror 7 and the object plane 9 and the z-distance PA2 between the object plane 9 and the pupil plane 12b. It thus holds true that: PA=PA1+PA2. Alternatively, the pupil distance PA can also be measured in the beam direction.

An illumination pupil region of the illumination pupil 12a impinged upon by the illumination light 3 is adapted to an exit pupil of the projection optical unit 10, as will be explained below.

In order to facilitate the representation of positional relationships, a Cartesian xyz-coordinate system will be used hereinafter. The x-direction runs perpendicularly to the plane of the drawing into the latter in FIG. 1. In FIG. 1, the y-direction runs to the right. The z-direction runs downwards in FIG. 1. Coordinate systems used in the drawing have x-axes running parallel to one another in each case. The course of a z-axis of said coordinate systems follows a respective principal direction of the illumination light 3 within the figure respectively under consideration.

The object field 8 has an arcuate or partly circular shape and is delimited by two mutually parallel circle arcs and two straight side edges which run in the y-direction with a length y₀ and are at a distance x₀ from one another in the x-direction. The aspect ratio x₀/y₀ is 13 to 1. An insert in FIG. 1 shows a plan view of the object field 8, this plan view not being true to scale. A boundary shape 8a is arcuate. In an alternative and likewise possible object field 8, the boundary shape thereof is rectangular, likewise with aspect ratio x₀/y₀.

The reticle 12 is displaced through the object field 8 in an object displacement direction y during a projection exposure.

The projection optical unit 10 is indicated only in part and highly schematically in FIG. 1. An object field side numerical aperture 13 and an image field side numerical aperture 14 of the projection optical unit 10 are illustrated. The image field-side numerical aperture 14 can be in the range between 0.2 and 0.7 and can be 0.3, 0.33, 0.4, 0.45, 0.5, 0.55 or else 0.6, for example. Between indicated optical components 15, 16 of the projection optical unit 10, which components may be embodied, for example, as mirrors that are reflective for the EUV illumination light 3, there are situated further optical components—not illustrated in FIG. 1—of the projection optical unit 10 for guiding the illumination light 3 between these optical components 15, 16. The projection optical unit 10 is embodied as an obscured imaging optical unit. The projection optical unit 10 has a last mirror in the beam path of the illumination and imaging light 3, said mirror having a passage opening for the illumination and imaging light 3. A reflection surface of this last mirror of the projection optical unit 10 is interrupted in the region of this passage opening, and this leads to an obscuration. An exit pupil of the projection optical unit 10 accordingly has an obscuration exit pupil region. An edge contour of the obscuration exit pupil region of the projection optical unit 10 can be specified for the illumination and imaging light 3 by way of an obscuration stop in the beam path of the projection optical unit 10.

The projection optical unit 10 images the object field 8 into an image field 17 in an image plane 18 on a wafer 19, which, like the reticle 12 as well, is carried by a holder (not depicted in detail). Both the reticle holder and the wafer holder are displaceable both in the x-direction and in the y-direction by use of corresponding displacement drives. An installation space requirement of the wafer holder is illustrated as a rectangular box at 20 in FIG. 1. The installation space requirement 20 is cuboid with an extent in x-, y- and z-directions that is dependent on the component parts to be accommodated herein. The installation space requirement 20 has, for example, proceeding from the center of the image field 17, an extension of 1 m in the x-direction and in the y-direction. In the z-direction, too, the installation space requirement 20 has, proceeding from the image plane 18, an extension of 1 m, for example. The illumination light 3 has to be guided in the illumination optical unit 11 and the projection optical unit 10 in such a way that it is in each case guided past the installation space requirement 20.

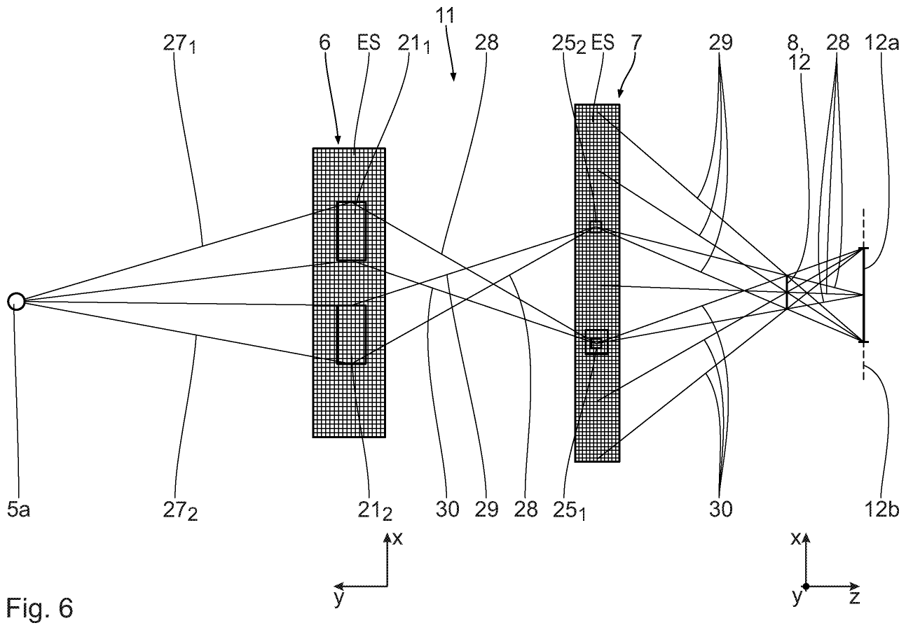

The transfer facet mirror 6 has a multiplicity of transfer facets 21 which are also denoted as first facets. The transfer facet mirror 6 may be embodied as a MEMS mirror. The transfer facets 21 each have a plurality of individual mirrors ES (cf. also FIGS. 4 and 6) which are switchable between at least two tilt positions and which are embodied as micromirrors. The individual mirrors ES may be embodied as micromirrors tiltable in a driven manner about two rotation axes perpendicular to one another.

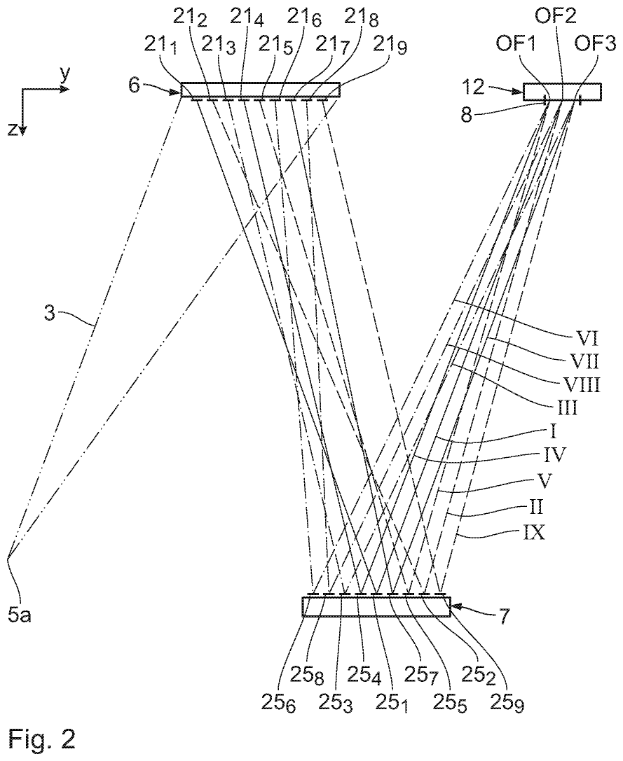

Of the transfer facets 21, a line having a total of nine transfer facets 21 is depicted schematically in the yz-sectional view according to FIG. 2, said transfer facets being indexed from left to right by 21₁ to 21₉ in FIG. 2. In actual fact, the transfer facet mirror 6 has a significantly greater multiplicity of the transfer facets 21. The individual mirrors ES of the transfer facet mirror 6 are grouped in a plurality of transfer facets 21. These transfer facets 21 are also denoted as individual mirror groups, as virtual field facets or as virtual facet groups. An individual mirror group is a group of individual mirrors ES of the first facet mirror 6 which are imaged into the object field 8 by the same second facet 25.

Each of the transfer facets 21 guides a component of the illumination light 3, which is also denoted as illumination light component beam, via an illumination channel for partial or complete illumination of the object field 8. Via said illumination channel and an illumination light component beam 3ᵢ guided via the latter, exactly one illumination specification facet 25 of the illumination specification facet mirror 7 is assigned in each case to one of the individual mirror groups or transfer facet groups. In principle, each of the illumination specification facets 25 may for their part in turn be constructed from a plurality of individual mirrors. The illumination specification facets 25 are also denoted hereinafter as second facets. To the extent that the second facet mirror 7 is arranged in the region of a pupil plane of the illumination optical unit 11, the illumination specification facets 25 are also referred to as pupil facets.

For further details of possible embodiments of the transfer facet mirror 6 and the projection optical unit 10, reference is made to WO 2010/099 807 A.

At least some of the illumination specification facets 25 illuminate only a partial zone or partial field of the object field 8. Said partial fields are very individually shaped and, moreover, are dependent on the desired illumination direction distribution (pupil shape) in the object field 8, i.e., the illumination setting. The illumination specification facets 25 are therefore illuminated by very differently shaped virtual field facets, the shape of which corresponds precisely to the shape of the respective partial field to be illuminated. Moreover, each illumination specification facet 25 contributes to different regions of the pupil depending on the location in the object field 8.

The illumination specification facet mirror 7 may be embodied as a MEMS mirror, particularly if each of the illumination specification facets 25 is constructed from a plurality of individual mirrors ES (cf. FIG. 6). The illumination specification facets 25 are micromirrors switchable between at least two tilt positions. The illumination specification facets 25 are embodied as micromirrors which are tiltable in a driven manner about two mutually perpendicular tilt axes continuously and independently, i.e., said micromirrors may be positioned into a multiplicity of different tilt positions.

One example of a specified assignment of individual transfer facets 21 to the illumination specification facets 25 is depicted in FIG. 2. The illumination specification facets 25 in each case assigned to the transfer facets 21₁ to 21₉ are indexed according to this assignment. On account of this assignment, the illumination specification facets 25 are illuminated from left to right in the following order: 25₆, 25₈, 25₃, 25₄, 25₁, 25₇, 25₅, 25₂ and 25₉.

The indices 6, 8 and 3 of the facets 21, 25 include three illumination channels VI, VIII and III which illuminate three object field points OF1, OF2, OF3 from a first illumination direction, the said object field points being numbered from left to right in FIG. 2. The indices 4, 1 and 7 of the facets 21, 25 belong to three further illumination channels IV, I, VII which illuminate the three object field points OF1 to OF3 from a second illumination direction. The indices 5, 2 and 9 of the facets 21, 25 belong to three further illumination channels V, II, IX which illuminate the three object field points OF1 to OF3 from a third illumination direction. The illumination channels I to IX are assigned corresponding illumination light component beams 3₁ to 3₉.

The illumination directions assigned to
the illumination channels VI, VIII, III,
the illumination channels IV, I, VII and
the illumination channels V, II, IX
   are identical in each case. The assignment of the transfer facets 21 to the illumination specification facets 25 is therefore such that this results in a telecentric illumination of the object field 8 in the case of the illumination example illustrated pictorially.

The object field 8 can be illuminated via the transmission facet mirror 6 and the illumination specification facet mirror 7 in the style of a specular reflector. The principle of the specular reflector is known from US 2006/0132747 A1.

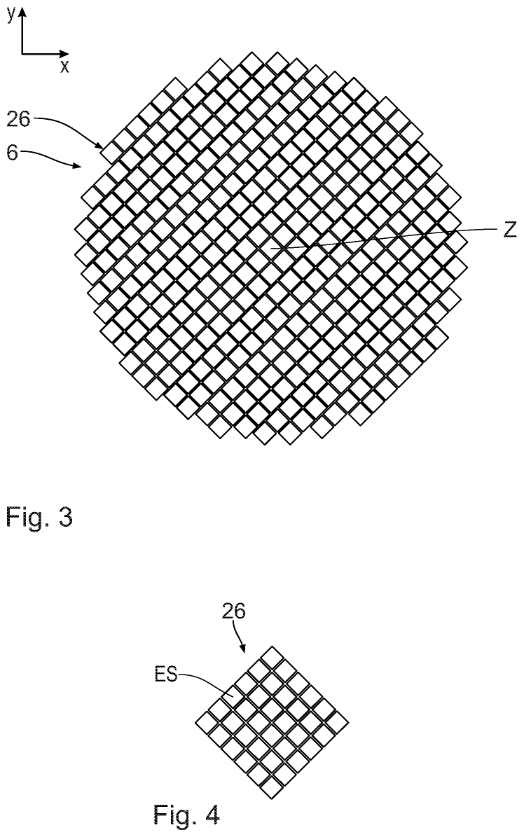

FIG. 3 shows a plan view of the first facet mirror 6. The latter has a regular array arrangement of individual mirror units 26, which are bounded by squares in FIG. 3. Each of the individual mirror units 26 is embodied as a sub-array of N×M of the individual mirrors ES (cf. FIG. 4). This sub-array has a plurality of array lines which extend along a line direction that corresponds to an angle bisector of the xy-coordinate system. Some of the mutually adjacent array lines are offset from one another by a proportion of an extent of one of the individual mirror units 26, in particular by half of this extent of the respective individual mirror unit 26 along the array line. Depending on the embodiment of the facet mirror 6, it is possible to manage entirely without such an offset, and so this results in an array arrangement constructed entirely of lines and columns. Alternatively, all array lines can be offset from one another. Different absolute offset values between different adjacent array parts are also possible, depending on the embodiment of the facet mirror 6 and depending on the requirements placed on a positioning of the individual mirror units 26.

FIG. 4 shows one of the individual mirror units 26, still schematically but with more detail. What is shown is a subdivision of the individual mirror unit 26 into the sub-array of 6×6 individual mirrors ES in this case. Thus, each of the individual mirror units 26 has 36 of the individual mirrors ES in the embodiment illustrated. Thus, N=6 and M=6 applies to the N×M sub-array arrangement in the example according to FIG. 4. N and M can be the same, can be different and can each be in the range between 2 and 64, for example, 4, 8, 16, 32 or 64. Values other than powers of two are also possible for N and M, for example, 25 or 50. For example, a 12×12 or 24×24 sub-array is also possible.

In the embodiment depicted in FIG. 3, the first facet mirror 6 has an arrangement of the individual mirror units 26 within a circular envelope. Alternatively, the first facet mirror 6 can also comprise the individual mirror units 26 within an envelope with an elliptical, rectangular or else polygonal boundary.

In each case one of the individual mirror units 26 may contain a plurality of complete or partial individual mirror groups, which guide the illumination light 3 to different second facets 25 and which are imaged into the object field 8 in a manner superimposed on one another. The individual mirror groups can extend over a plurality of the individual mirror units 26.

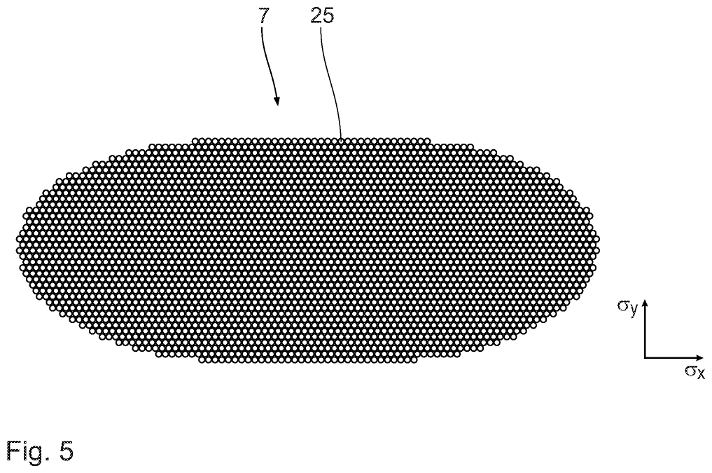

FIG. 5 shows, in turn, a plan view of the second facet mirror 7.

The second facets 25 of the second facet mirror 7 are embodied with a circular boundary and are present in hexagonal close-packed form. Second facets 25 with a rectangular or polygonal boundary, in particular a hexagonal boundary, are also an alternative to second facets 25 with a circular boundary. The second facets 25 can be embodied in turn as individual mirror units in the style of the individual mirror units of the first facet mirror 6 and can be subdivided into a plurality of individual mirrors in the style of the individual mirrors ES in this case. In principle, with regard to the subdivision into individual mirrors and individual mirror units, a structure of the second facet mirror 7 can correspond to the structure of the first facet mirror 6.

In the embodiment according to FIG. 5, each of the second facets 25 can also be embodied as a monolithic facet.

In the second facet mirror 7, the second facets 25 are arranged within an envelope with an elliptical boundary. Alternatively, other envelope shapes are also possible here, for example, a circular envelope, a rectangular envelope and also an envelope with a polygonal boundary.

FIG. 6 shows, once again schematically, an embodiment of the illumination optical unit 11, in which the first facet mirror 6 is arranged in the region of a field plane of the illumination optical unit 11, and the second facet mirror 7 is arranged at a distance from a pupil plane of the illumination optical unit 11, in particular at a distance from the pupil plane 12b (cf. also FIG. 1).

The two facet mirrors 6 and 7 are embodied as MEMS mirrors and comprise a multiplicity of individual mirrors ES.

FIG. 6 illustrates a beam path of selected individual rays between the intermediate focus 5a and the entrance pupil 12a. In particular, FIG. 6 elucidates, by way of example, a course of two illumination channels 27₁, 27₂, which are each guided via a transfer facet 21₁, 21₂ of the first facet mirror 6 and an illumination specification facet 25₁, 25₂ of the second facet mirror 7. Each of the transfer facets 21ᵢ is constructed as a 7×14 array of individual mirrors ES, wherein a longer extent of this array runs in the x-direction and a shorter extent of the array runs in the y-direction, in a manner adapted to the aspect ratio of the object field 8.

For illustrative purposes, the two facet mirrors 6, 7 are depicted rotated through 90° about the x-axis in the illustration according to FIG. 6, and so they are visible in an xy-plan view, whereas further component parts, for example, the reticle 12 and the entrance pupil 12a, are shown in an xz-meridional section.

The illumination specification facet 25ᵢ of the respective illumination channel 27ᵢ is embodied as a 2×2 array of individual mirrors ES of the illumination specification facet mirror 7.

In addition to the course of the two illumination channels 27ᵢ between the intermediate focus 5a and the entrance pupil 12a, FIG. 6 also illustrates courses of selected individual rays that are assigned to different illumination angles. In this case, chief rays 28 are illustrated, which each run through a center of the entrance pupil 12a, and marginal or coma rays 29 and 30, which delimit the entrance pupil 12a in the direction of the x-coordinate on the one side and the other side.

The illumination channel 27₁ is firstly delimited by one of the chief rays 28 and secondly delimited by one of the marginal rays 30, i.e., it covers a portion of an entire entrance pupil 12a illuminated by way of the illumination pupil 11 in the shown setting assignment.

The illumination channel 27₂ is firstly delimited by one of the chief rays 28 in turn and secondly delimited by one of the marginal rays 29, i.e., it covers a complementary illumination angle range within the entrance pupil 12a.

The two illumination channels 27₁, 27₂ illuminate the entire object field 8.

Alternatively, illumination channels 27ᵢ in which it is not the entire object field 8 but only a partial field that is illuminated and/or in which it is not only a portion of the entrance pupil 12a but the entire entrance pupil 12a that is illuminated are also possible.

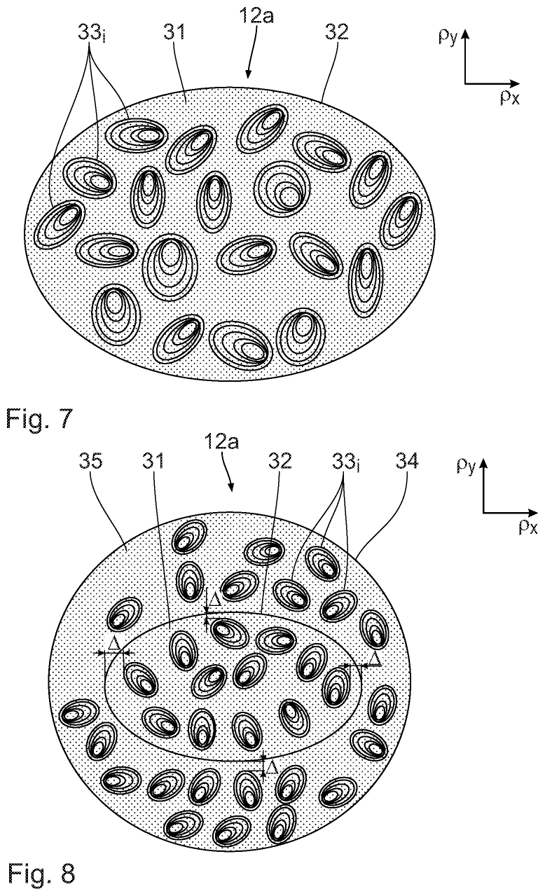

FIG. 7 illustrates an obscuration illumination pupil region 31 in the interior of an embodiment of the illumination pupil 12a whose edge region is not depicted in FIG. 7. In terms of its edge contour, an envelope 32 of the obscuration illumination pupil region 31 is adapted to an edge contour of the embodiment of the projection optical unit 10 corresponding to the obscuration exit pupil region. The envelope 32 specifies a core section of the illumination pupil 12a, located in which are incidence locations 33ᵢ of the illumination channels 27i of the channel-by-channel mixed illumination, which are specified by way of the facet mirrors 6, 7 of the illumination optical unit 11. These incidence locations 33ᵢ are also denoted as spots. The incidence locations 33ᵢ have an illumination light intensity distribution which is illustrated by isolines in FIG. 7. The illumination intensity increases inwardly within the incidence locations 33ᵢ, wherein a maximum of the illumination intensity is not located in the center of the respective incidence location 33ᵢ but regularly decentered. The incidence locations 33ᵢ regularly have an elliptical shape or else a circular shape. A different, less regular shape is also possible. Outside of the incidence locations 33ᵢ, the obscuration illumination pupil region 31 is not impinged upon, or not impinged upon to any noticeable extent, by the illumination light 3, even within the envelope 32. The distribution of regions of the respective illumination pupil 12a impinged upon by the illumination light 3 is also denoted as illumination setting.

To specify the illumination pupil 12a with the obscuration illumination pupil region 31 according to FIG. 7, tilt angles of the individual mirrors ES of the first facets 21ᵢ, which belong to the illumination channels 27ᵢ and the incidence locations 33i, are set in such a way that the incidence locations 33ᵢ within the envelope 32 have a distribution that is as uniform as possible and fill the entire obscuration illumination pupil region 31.

Thus, in absolute pupil coordinates ρₓ, ρ_{y} which represent a measure for a respective absolute illumination angle, the envelope 32, for its part, has an elliptical shape, i.e., deviates from a circular shape. The envelope 32 can also deviate differently from the circular shape.

FIG. 8 illustrates a further embodiment of an illumination pupil 12a, in which incidence locations 33ᵢ are arranged distributed within an outer envelope 34 of an outer illumination pupil region 35 of the illumination pupil 12a. The outer envelope 34 is circular in the absolute pupil coordinates ρₓ, ρ_{y} which represent a measure for the illumination angle at assigned object field points of the object field 8. The outer illumination pupil region 35 is located between the envelope 32 of the obscuration pupil region 31 on the one hand and the outer envelope 34 on the other hand.

The envelope 32 of the obscuration illumination pupil region 31, which like the illumination pupil 12a according to FIG. 7 is adapted to the obscuration exit pupil region of the projection optical unit 10, is located within the circular outer envelope 34. The incidence locations 33ᵢ of the illumination channels 27ᵢ are arranged with such a distribution within the outer envelope 34 that all incidence locations 33ᵢ have a minimum distance Δ from the envelope 32 of the obscuration illumination pupil region 31. This minimum distance Δ can be in the range of 0.1% to 5% of a typical diameter of the obscuration pupil region 31 in relative pupil coordinates σₓ, σ_{y} that have been normalized to the maximum illumination angle in each case.

As a result, neither the inner obscuration illumination pupil region 31 nor the outer illumination pupil region 35 is impinged upon by the illumination light 3 in an illumination pupil surround around the envelope 32, i.e., in an illumination pupil surround corresponding to a region of the exit pupil of the projection optical unit 10 adjacent to an edge of the obscuration exit pupil region.

The illumination pupil 12a is not impinged upon by the illumination light 3 between the outer envelope 34 and an outer edge of the entire illumination pupil 12a, which is not depicted in FIG. 8. In an alternative illumination pupil 12a according to FIG. 8, the outer envelope 34 and the outer edge of the entire illumination pupil 12a coincide.

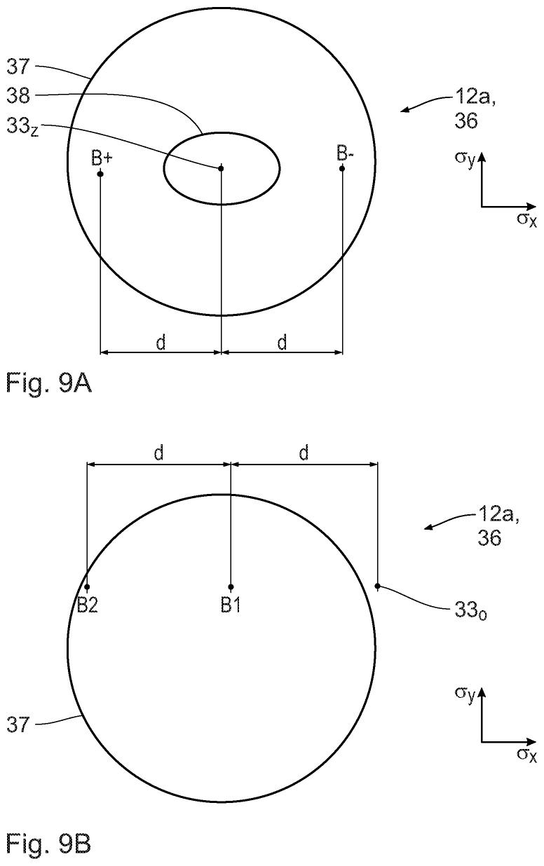

Hereinafter, FIGS. 9A and 9B are used to explain different variants of a dark field illumination which can be set by use of the illumination optical unit 11 by way of an appropriate selection of the illumination channels 27ᵢ by appropriately tilting the individual mirrors ES of the facet mirrors 6 and 7.

FIG. 9A shows a pupil of the projection exposure apparatus 1, which can be understood to be the illumination pupil 12a on one hand and an exit pupil 36 of the projection optical unit 10 on the other hand. This pupil 12a, 36 has an outer pupil boundary 37 which specifies a numerical aperture of the corresponding optical unit 11, 10 of the projection exposure apparatus 1. In the case of the illumination pupil 12a of the illumination optical unit 11, the outer pupil edge 37 specifies a maximally possible illumination angle for the object field 8 in the direction of a respective pupil radius. In the case of the exit pupil 36 of the projection optical unit 10, the outer pupil edge 37 specifies the image field-side numerical aperture. This outer pupil edge 37 is regularly specified by an aperture stop of the projection exposure apparatus 1. In the case of the pupil 12a, 36 according to FIG. 9A, the outer pupil edge 37 is circular but can also have a boundary of any other shape, e.g., elliptical or deviating from the circular shape in any other way.

Moreover, the exit pupil 36 has an obscuration exit pupil region 38. The latter is regularly specified by an obscuration stop of the projection exposure apparatus 1 such that, in particular, a passage opening in the last mirror of the projection optical unit 10 is, in defined fashion, not impinged upon by the illumination and imaging light 3. The obscuration exit pupil region 38 has an elliptical boundary. In terms of its arrangement and shape, this boundary corresponds to the envelope 32 of the obscuration illumination pupil region 31 according to FIGS. 7 and 8.

FIG. 9A illustrates an illumination light incidence location 33_{z} at the center of the illumination pupil 12a, which is depicted in normalized pupil coordinates σₓ, σ_{y}. At the same time, this central incidence location 33_{z} is located at the center of the obscuration exit pupil region 38.

The illumination of the object field 8 and structured reticle 12 using the illumination channel 27_{z} from the direction of the incidence location 33_{z} in the illumination pupil 12a creates B+ and B− orders of diffraction in the exit pupil 36. These B+, B− orders of diffraction are located between the envelope of the obscuration aperture region 38 and the outer pupil edge 37 of the exit pupil 36. Thus, this is an instance of dark field illumination, in which the zeroth-order illumination light 3 does not reach the image field 17 but is incident on the obscuration stop of the projection optical unit 10, whereas the illumination light of the B+, B− orders of diffraction passes both the obscuration stop and the aperture stop of the projection optical unit 10 and reaches the image field 17 for imaging the respective structure of the reticle 12 on the wafer 19.

Along the pupil coordinate σₓ, which is also denoted as diffraction pupil coordinate of the exit pupil 36 below, the structures on the reticle 12 lead to a diffraction of the imaging light 3 downstream of the reticle 12. A diffraction path d, i.e., a distance between the B+ and B− orders of diffraction on the one hand and the incidence location 33_{z} of the zeroth order of diffraction, extends along this diffraction pupil coordinate σₓ.

FIG. 9B illustrates a further variant of a dark field illumination. In this case, an incidence location 33₀ of a zeroth order of diffraction of the imaging light 3 is located on structures of the reticle 12 outside of the outer pupil edge 37 of the exit pupil 36, i.e., it is blocked by the aperture stop of the projection optical unit 10. Along the diffraction pupil coordinate σₓ, in each case spaced apart from one another by the diffraction path d, B1 and B2 orders of diffraction of the imaging light 3 diffracted at the structures of the reticle 12 arise within the outer pupil edge 37 of the exit pupil 36 and are then able to reach the image field 17 for imaging the corresponding structure of the reticle 12 on the wafer 19. The exit pupil 36 according to FIG. 9B can be a non-obscured exit pupil or else an obscured exit pupil; this is not depicted in detail in FIG. 9B.

Corresponding dark field illuminations, as described above in conjunction with FIGS. 9A and 9B, can in principle be combined with the illumination setting variants explained in this document overall, by way of an appropriate setting of the individual mirrors ES of the facet mirrors 6 and 7 of the illumination optical unit 11. In the case of the dark field illumination according to FIG. 9B, individual mirrors ES on the illumination specification facet mirror 7, which belong to illumination angles outside of an outer pupil edge 37 of the exit pupil 36, are used to specify the incidence location 33₀.

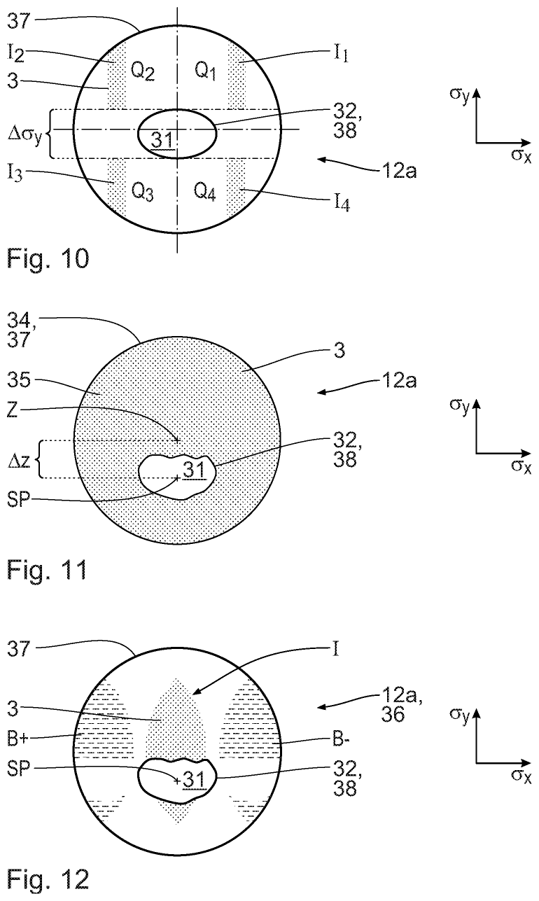

FIG. 10 shows a further embodiment of an adapted illumination pupil 12a that is impinged upon by the illumination light 3. Components and functions which have already been explained above with reference to FIGS. 1 to 9, and in particular with reference to FIGS. 7 to 9, bear the same reference signs and will not be discussed in detail again.

The illumination pupil 12a according to FIG. 10 is not impinged upon by the illumination light 3 within the envelope 32 of the obscuration illumination pupil region 31. The illumination pupil 12a according to FIG. 10 is thus not impinged upon by the illumination light 3 in illumination pupil regions that correspond to the obscuration exit pupil region (cf. 38 in FIG. 9A) of the projection optical unit 10. The envelope 32 is horizontally elliptical in the representation according to FIG. 10 and centred in relation to the outer pupil edge 37 of the illumination pupil 12a.

The illumination pupil 12a according to FIG. 10 is impinged upon by the illumination light 3 in four strip-shaped pupil regions I₁, I₂, I₃ and I₄, which are each located in one of the four quadrants Q₁, Q₂, Q₃ and Q₄ of the illumination pupil 12a. In principle, the illumination pupil 12a according to FIG. 10 thus represents a quadrupole illumination setting with four illumination poles I₁ to I₄. The illumination pupil 12a according to FIG. 10 is not impinged upon by the illumination light 3 in an illumination pupil coordinate range Δσ_{y} of a cross diffraction pupil coordinate σ_{y} perpendicular to the diffraction pupil coordinate σₓ. This illumination pupil coordinate range Δσ_{y} corresponds to an extent of the obscuration aperture region 38 along this cross diffraction pupil coordinate σ_{y}, as illustrated in FIG. 10. An illumination strip formed by the illumination poles I₂, I₃ on the one hand and I₁, I₄ on the other hand is in each case interrupted in this illumination pupil coordinate range Δσ_{y}.

This arrangement of the illumination poles I₁ to I₄ of the illumination setting 12a according to FIG. 10 ensures that orders of diffraction diffracted along the diffraction pupil coordinate σₓ in the exit pupil 36 do not arrive in the obscuration aperture region 38 as they would undesirably not contribute to a superposition for imaging corresponding structures of the reticle 12 in that case.

Once again, a distribution of incidence locations 33ᵢ of illumination channels 27ᵢ as already explained above in the context of FIGS. 7 and 8 can be present within the illumination poles I₁ to I₄.

FIG. 11 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 10, and particularly with reference to FIGS. 7 to 10, bear the same reference signs and will not be discussed in detail again.

The illumination setting 12a according to FIG. 11 gives rise to an obscuration illumination pupil region 31, the pose and boundary of which within the illumination pupil 12a is adapted to an associated obscuration exit pupil region 38. In terms of its shape, the envelope 32 of the obscuration illumination pupil region 31 corresponds to the shape of the envelope of the obscuration exit pupil region 38. This shape of the envelope 32 is irregular and can be approximated to a first approximation by a horizontal ellipse (cf. FIG. 10). The envelope 32 deviates from a circular shape.

The obscuration illumination pupil region 31 and the associated obscuration exit pupil region 38 have a non-centric geometric centroid SP. This centroid SP is spaced apart, i.e., decentered, from a center of the entrance pupil 12a or exit pupil 36 by a distance Δz. Δz can be in the range between 0.5% and 45% of a typical diameter of the entrance pupil 12a. This decentration Δz has been depicted in exaggerated fashion in FIG. 11.

The entrance pupil 12a according to FIG. 11 is impinged upon by the illumination light 3 only between the envelope 32 of the obscuration illumination pupil region 31 and the outer pupil edge 37. Incidence locations 33ᵢ of the illumination channels 27ᵢ can be arranged in tightly packed and uniformly distributed fashion, once again, in this impingement region between the envelope 32 and the outer pupil edge 37.

In the illumination setting 12a according to FIG. 11, the pupil is illuminated directly adjacently to the envelope 32. Alternatively, a distance Δ can once again be present between the envelope 32 and such incidence points 33i, as already explained above in conjunction with FIG. 8.

FIG. 12 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 11, and particularly with reference to FIGS. 7 to 11, bear the same reference signs and will not be discussed in detail again.

In the case of the illumination pupil 12a according to FIG. 12, the envelope 32 of the obscuration illumination pupil region 31 adapted to the obscuration exit pupil region 38 is once again completely omitted. An illumination is implemented exclusively outside of this envelope 32 in a central illumination pole I which has an approximately biconvex lens shape. The illumination pole I can have a boundary shape denoted as leaf shape. The illumination pole I of the illumination pupil 12a according to FIG. 12 has such an extent that there is an illumination of the illumination pupil 12a on both sides of the envelope 32 along the cross diffraction pupil coordinate σ_{y}.

In addition to the illumination pole I, the pose of which in the illumination pupil 12a corresponds to the pose of a zeroth order of diffraction of the imaging light 3 in the exit pupil 36, FIG. 12 also illustrates the B+, B− orders of diffraction within the exit pupil 36. A boundary of the illumination pole I is such that the B+, B− orders of diffraction are still located completely within the outer pupil edge 37. A “lens curvature” of the edge contour of the illumination pole I corresponds to a curvature of the outer pupil edge 37.

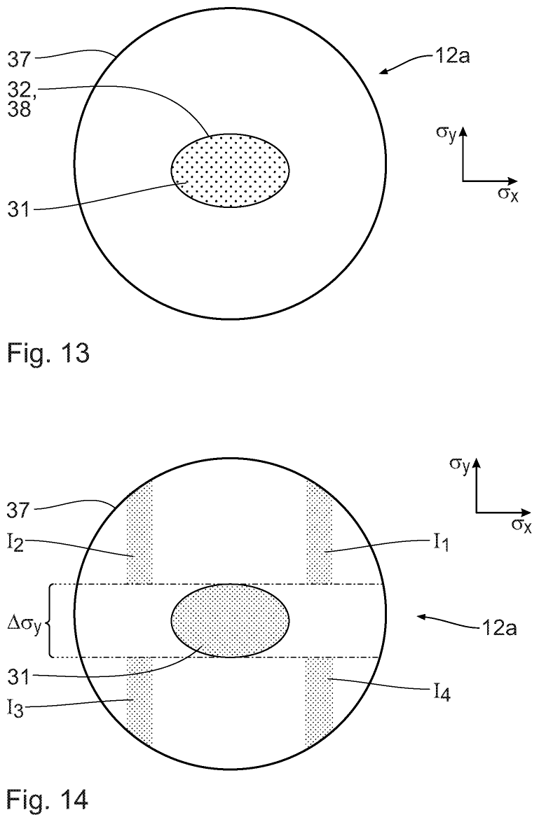

FIG. 13 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 12, and particularly with reference to FIGS. 7 to 12, bear the same reference signs and will not be discussed in detail again.

The entrance pupil 12a according to FIG. 13 is a variant of a dark field illumination. The entrance pupil 12a according to FIG. 13 is illuminated only within the envelope 32, i.e., in the obscuration illumination pupil region 31, which is once again adapted to the obscuration exit pupil region 38 of the projection optical unit 10. The envelope 32 has an elliptical embodiment in the normalized pupil coordinates σₓ, σ_{y}, wherein a semimajor axis of this ellipse runs along the σₓ coordinate. The entrance pupil 12a is not impinged upon by the illumination light 3 between the envelope 32 and the outer pupil boundary 37.

FIG. 14 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 13, and particularly with reference to FIGS. 7 to 13, bear the same reference signs and will not be discussed in detail again.

The illumination pupil 12a according to FIG. 14 can be understood to be a superposition of the illumination pupils 12a according to FIGS. 10 and 13. Thus, it is firstly the obscuration illumination pupil region 31 and secondly the four illumination poles I₁, I₂, I₃ and I₄ that are illuminated.

FIG. 15 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 14, and particularly with reference to FIGS. 7 to 14, bear the same reference signs and will not be discussed in detail again.

In principle, the illumination pupil 12a according to FIG. 15 corresponds to that according to FIG. 8, wherein there is a uniform illumination of the entrance pupil 12a with the illumination light 3 within the outer envelope 34. To the extent that this uniform illumination within the outer envelope 34 by use of distributed incidence locations 33ᵢ of illumination channels 27ᵢ is implemented in a manner corresponding to that explained above in the context of FIGS. 7 and 8, incidence locations 33ᵢ can also be located on the envelope 32 of the obscuration illumination pupil region 31 in an alternative variant of the entrance pupil 12a.

FIG. 16 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 15, and particularly with reference to FIGS. 7 to 15, bear the same reference signs and will not be discussed in detail again.

The entrance pupil 12a according to FIG. 16 is a variant of the entrance pupil 12a according to FIG. 15, wherein, within the scope of illuminating the outer envelope 34 with the illumination light 3 in the case of the entrance pupil 12a according to FIG. 16, care is taken to ensure that the entrance pupil 12a is not impinged upon by the illumination light 3 in the surround of the envelope 32, in particular at a distance Δ from same. Thus, a distance of at least 2 Δ is present in the entrance pupil 12a between illumination light 3 within the envelope 32 on the one hand and illumination light 3 outside of the envelope 32 on the other hand. In this respect, the entrance pupil 12a according to FIG. 16 corresponds to that according to FIG. 8.

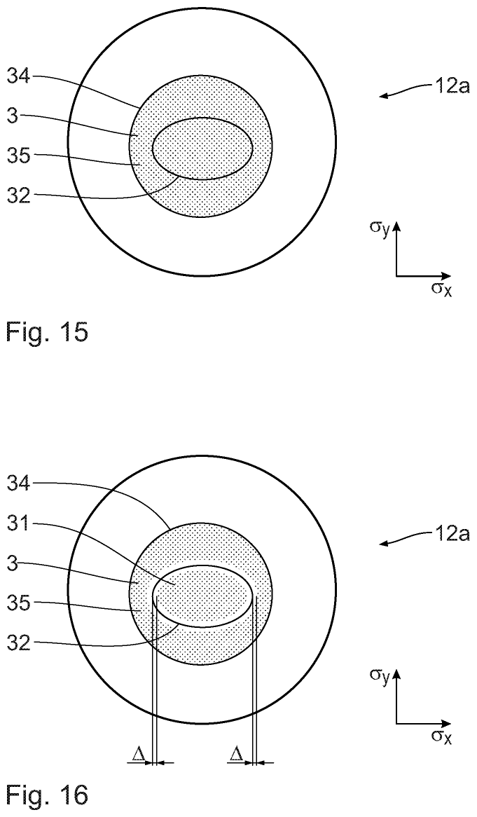

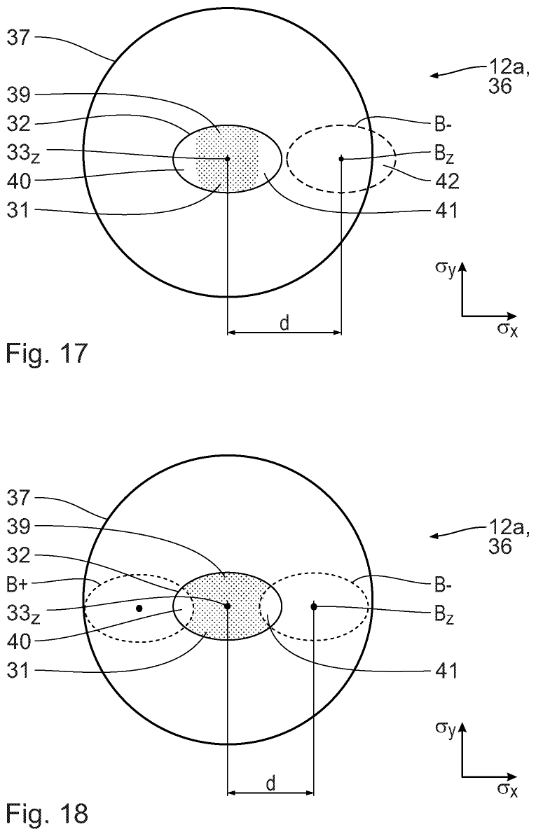

FIG. 17 is used to elucidate a further embodiment of the illumination pupil 12a hereinafter, said illumination pupil being adapted to the associated exit pupil of the projection optical unit 10. Components and functions corresponding to those which have already been explained above with reference to FIGS. 1 to 16, and particularly with reference to FIGS. 7 to 16, bear the same reference signs and will not be discussed in detail again.

The illumination setting 12a according to FIG. 17 represents a variant of a dark field illumination. In this case, it is not the entire obscuration illumination pupil region 31 within the envelope 32 that is illuminated but only a portion 39 around a central incidence location 33_{z}. A σₓ-extent of the portion 39 around the central incidence location 33_{z}, i.e., around the center of the obscuration illumination pupil region 31, is smaller than the σₓ-extent of the entire obscuration illumination pupil region 31, and so clear regions 40, 41 that are not impinged upon by the illumination light 3 remain within the obscuration illumination pupil region 31 in FIG. 17, to the right and left of the portion 39.

In a manner comparable to the illustration according to FIGS. 9A and 12, FIG. 17 also depicts a B− order of diffraction in the exit pupil 36, diffracted at corresponding structures of the reticle 12. A center B_{z} of this B− order of diffraction is spaced apart from the center 33_{z} of the illuminated portion 39 within the obscuration illumination pupil region 31 by the diffraction path d along the diffraction pupil coordinate σₓ. At the same time, this illuminated portion 39 represents a zeroth order of diffraction within the exit pupil 36.

The edge contour of the portion 39 is adapted to the diffraction path d such that the diffracted portion 39 in the B− order of diffraction is located completely within the outer pupil edge 37 of the exit pupil 36. A projection 42 of the B− order of diffraction beyond the outer pupil edge 37 corresponds in terms of shape and size to the clear region 41, to the right in FIG. 17, within the envelope 32.

FIG. 18 is used to elucidate a further embodiment of the illumination pupil 12a hereinafter, said illumination pupil being adapted to the associated exit pupil 36 of the projection optical unit 10. Components and functions corresponding to those which have already been explained above with reference to FIGS. 1 to 17, and particularly with reference to FIGS. 7 to 17, bear the same reference signs and will not be discussed in detail again.

FIG. 18, too, represents a variant of an illumination pupil 12a which can be used for dark field illumination.

Once again, it is not the entire obscuration illumination pupil region that is illuminated but only a portion 39, with the result that clear regions 40, 41 through portions 39 to the left and right within the envelope 32 of the obscuration illumination pupil region 31 are not impinged upon by the illumination light 3. In terms of shape and size, these clear regions 40, 41 correspond to overlap regions of the obscuration illumination pupil region 31 with the two B−, B+ orders of diffraction of the exit pupil 36, once again diffracted at structures of the reticle 12, but this time with a diffraction path or diffraction distance d along the diffraction pupil coordinate σₓ−which, in relation to the diameter of the exit pupil 36, is smaller than the diffraction spacing d of the embodiment according to FIG. 17. On account of the smaller relative diffraction distance d, the B− and B+ orders of diffraction overlap in the clear regions 40, 41 with the obscuration illumination pupil region 31, which in terms of pose and shape corresponds to the zeroth order of diffraction within the exit pupil 36.

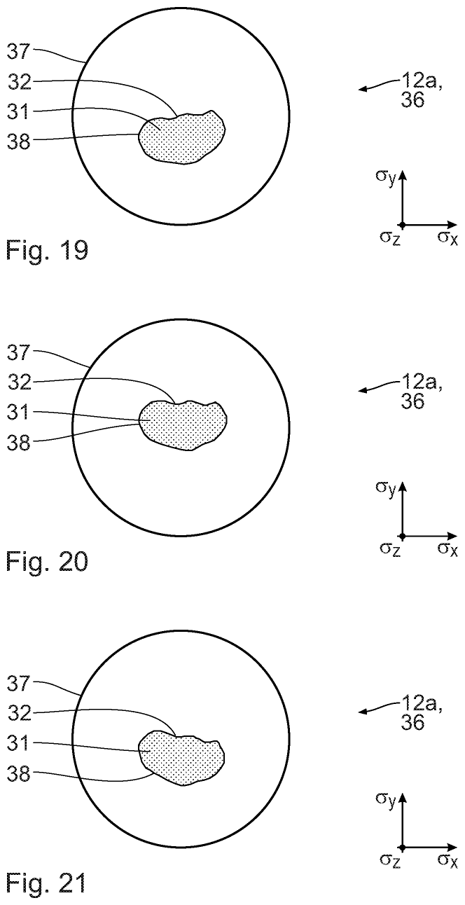

A further embodiment of an illumination pupil 12a, which in this case depends on the location in the object field 8 and which is adapted to an exit pupil 36 with the same object field dependence, is described below on the basis of FIGS. 19 to 21. Components and functions corresponding to those which have already been explained above with reference to FIGS. 1 to 18, and particularly with reference to FIGS. 7 to 18, bear the same reference signs and will not be discussed in detail again.

FIGS. 19 to 21 show the pupils 12a and 36 corresponding to one another, for three different x-positions of the object field 8, which are also denoted as field heights. FIG. 19 shows the entrance pupil 12a and the exit pupil 36 corresponding thereto, at a field height of x=−13 mm, i.e., at a left x-field edge of the object field 8. FIG. 20 shows the illumination pupil 12a and the exit pupil 36 corresponding thereto, at an x-field center (x=0 mm) of the object field 8. FIG. 21 shows the entrance pupil 12a and the exit pupil 36 corresponding thereto, at a right x-field edge (x=+13 mm) of the object field 8. Thus, depending on the x-object field coordinate, the object field 8 is illuminated with different illumination angle distributions in the case of the illumination setting with the illumination pupil 12a according to FIGS. 19 to 21.

In the case of the field height of x=0 mm (FIG. 20), there is a dark field illumination comparable to that according to FIG. 13, albeit with an irregular envelope 32 of the obscuration illumination pupil region 31 in the style of FIGS. 11 and 12. In the case of the field height of x=0, the obscuration illumination pupil region 31 of the illumination pupil 12a according to FIG. 20 is centred within the outer pupil edge 37.

At the left object field edge (field height x=−13 mm, cf. FIG. 19), the illumination pupil 12a, adapted to the exit pupil 36 at this field height of x=−13 mm, appears firstly displaced in the direction of the negative cross diffraction pupil coordinate σₓ−, i.e., downwards in FIG. 19, and slightly tilted anticlockwise through a σ_{z}-coordinate.

At the right object field edge (field height x=+13 mm, cf. FIG. 21), there is a corresponding −σ_{y}-displacement of the obscuration illumination pupil region 31, adapted to the exit pupil 36 at this field height of x=13 mm, albeit slightly tilted in equal but opposite fashion in the positive clockwise direction about the pupil coordinate oz in this case.

Alternative field-dependent illumination pupils 12a, in particular those adapted to corresponding field dependencies of the exit pupil 36, may also be present in the other illumination settings described here, in particular in the illumination settings with an obscuration illumination pupil region 31 that deviates from the circular shape, e.g., in the illumination pupils 12a with an elliptical envelope 32 or else in the illumination pupils 12a with an irregular envelope 32 (cf. FIGS. 11 and 12, for example).

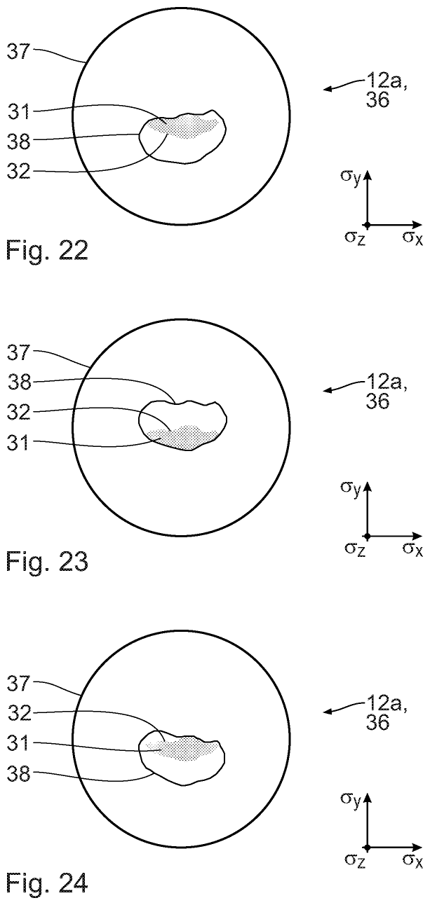

FIGS. 22 to 24 are used to explain a variant of a design for the illumination pupil 12a, by use of which an adaptation to a field-dependent exit pupil 36 is rendered possible. Components and functions that correspond to those which were already explained above with reference to FIGS. 1 to 21, in particular with reference to FIGS. 7 to 21 and especially with reference to FIGS. 19 to 21, bear the same reference signs and will not be discussed in detail again.

In the case of the pupil adaptation according to FIGS. 22 to 24, the respective illumination pupil 12a is not field-dependent, i.e., it has the same positioning, shape and envelope 32 of the obscuration illumination pupil region 31 within the outer pupil edge 37 independently of the field height (x=−13 mm, FIG. 22; x=0 mm, FIG. 23; x=+13 mm, FIG. 24). By contrast, in the embodiment according to FIGS. 22 to 24, the exit pupil 36 is field-dependent in the style of the field dependence of FIGS. 19 to 21. In comparison with the centred position in the case of the field height of x=0 mm (FIG. 23), an obscuration exit pupil region 38 is displaced in the −σ_{y}-direction and slightly tilted anticlockwise at the left field edge (x=−13 mm, cf. FIG. 22) and once again displaced in the negative σ_{y}-direction and slightly tilted clockwise about the pupil coordinate σ_{z} at the right field edge (x=+13 mm, cf. FIG. 24). In the case of the field-independent illumination pupil 12a according to FIGS. 22 to 24, the obscuration illumination pupil region 31 is smaller than the obscuration exit pupil region 38 to such an extent that the obscuration illumination pupil region 31 is always completely within the obscuration exit pupil region 38, independently of the field dependence of the pose and the orientation of the latter, as illustrated in FIGS. 22 to 24.

In a manner corresponding to the explanations relating to an x-dependence of the illumination pupil 12a and/or the exit pupil 36 given above, especially in conjunction with FIGS. 19 to 24, there can also be an adaptation of the illumination pupil 12a to a y-field dependence of the exit pupil 36 or to a combined x/y-field dependence of the exit pupil 36.

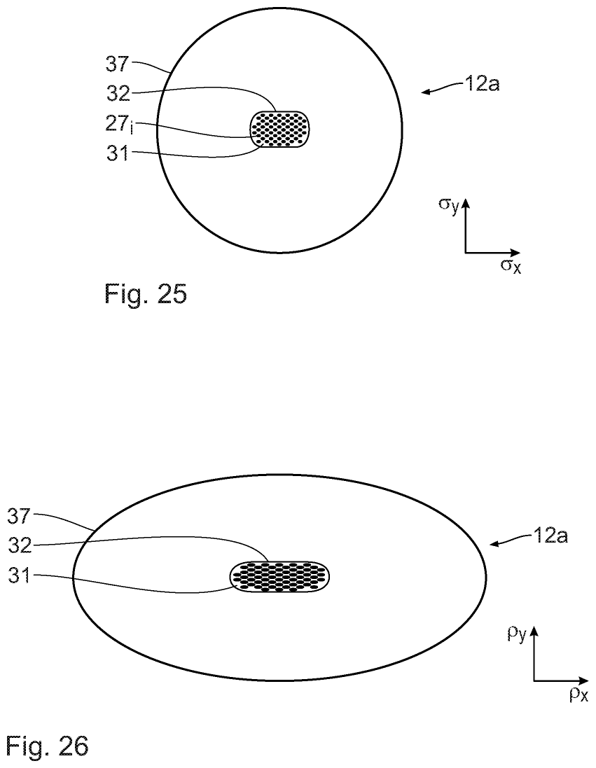

FIGS. 25 and 26 are used to elucidate a further embodiment of the illumination pupil 12a hereinafter, said illumination pupil being adapted to the associated exit pupil 36 of the projection optical unit 10. Components and functions corresponding to those which have already been explained above with reference to FIGS. 1 to 24, and particularly with reference to FIGS. 7 to 24, bear the same reference signs and will not be discussed in detail again.

The illumination pupil 12a according to FIGS. 25 and 26 is created with the aid of an illumination optical unit 11 of the projection exposure apparatus 1, in the case of which the first facet mirror 6 is arranged in a field plane of the illumination optical unit 11 and the second facet mirror 7 is arranged in a pupil plane of the illumination optical unit 11. For example, the illumination optical unit 11 can be equipped with a field facet mirror according to FIG. 3 and with a pupil facet mirror according to FIG. 5, wherein these facet mirrors may comprise either monolithic transfer facets 21 and illumination specification facets 25 or facets 21, 25 subdivided into individual mirrors ES, as has already been explained above.

The illumination pupil 12a according to FIGS. 25 and 26 is depicted in differently scaled pupil coordinate systems there.

FIG. 25 shows an illustration of the illumination pupil 12a chosen in normalized pupil coordinates σₓ, σ_{y}, in the case of which the outer pupil edge 37 in each case has the same σₓ/σ_{y} value at the location of the maximally possible object field illumination angle. Thus, in FIG. 25, the pupil coordinates σₓ, σ_{y} are normalized in such a way that this necessarily results in a circular outer pupil edge 37, independently of its actual shape in absolute pupil coordinates. The representations of the pupils in FIGS. 9 to 24 also use such normalized pupil coordinates σₓ, σ_{y}.

FIG. 26 shows the illumination pupil 12a according to FIG. 25 in absolute pupil coordinates ρₓ, ρ_{y}, i.e., in coordinates which represent a measure for the actual illumination angle on the object field. For example, such absolute pupil coordinates ρₓ, ρ_{y} are coordinates that represent a measure for a sine of the angle of incidence of the illumination light 3 on the object field 8. In these actual, absolute pupil coordinates ρₓ, ρ_{y}, the illumination pupil 12a is elliptical overall, with a semimajor axis along the pupil coordinate ρₓ. Moreover, in the absolute pupil coordinates, the illumination pupil 12a has an elliptical obscuration illumination pupil region 31 with a likewise elliptical envelope 32 with a semimajor axis along the pupil coordinate ρₓ. Incidence locations 33ᵢ of corresponding illumination channels 27ᵢ each conducting via a field facet 21 and a pupil facet 25 are indicated in FIGS. 25 and 26, said incidence locations being arranged in distributed fashion within the obscuration illumination pupil region 31.

A semi-axis ratio of the envelope 32 can differ from the semi-axis ratio of the outer pupil edge 37, and so the illustration in normalized pupil coordinates according to FIG. 25 yields a circular outer pupil edge 37 but no circular envelope 32 of the obscuration illumination pupil region 31.

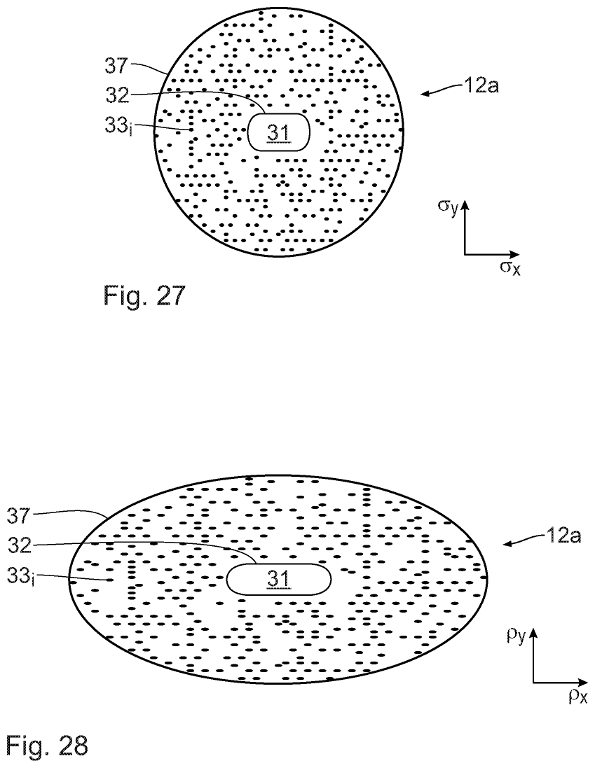

In the case of the illumination pupils 12a explained below on the basis of FIGS. 27 to 42 and in each case adapted to the corresponding exit pupil 36, the pupil is in each case depicted in normalized pupil coordinates σₓ, σ_{y} according to FIG. 25 in a first figure and in absolute pupil coordinates ρₓ, ρ_{y} corresponding to FIG. 26 in a subsequent figure.

The illumination pupils according to FIGS. 27 to 42 are also created with the aid of an illumination optical unit 11 in the style of a so-called fly's eye integrator, in the case of which the first facet mirror 6 is arranged in a pupil plane of the illumination optical unit 11 and the second facet mirror 7 is arranged in a pupil plane of the illumination optical unit 11.

A further pupil embodiment, which can be used in place of the above-described illumination pupils that are each adapted to an exit pupil, is described hereinafter on the basis of FIGS. 27 and 28. Components and functions that correspond to those which were already explained above with reference to FIGS. 1 to 26, in particular with reference to FIGS. 7 to 26 and specifically with reference to FIGS. 25 and 26, bear the same reference signs in particular and will not be discussed in detail again.

In the case of the illumination optical unit 12a according to FIGS. 27 and 28, the obscuration illumination pupil region 31 within the envelope 32 is not impinged upon by the illumination light 3. Incidence locations 33ᵢ of the illumination channels 27ᵢ set by way of the tilt angles of the facets 21, 25 of the illumination optical unit 11 are present in a distributed arrangement between the envelope 32 and the outer pupil edge 37, and so an illumination intensity that is homogeneous within specified tolerances is present per unit area of the illumination pupil 12a between the envelope 32 and the outer pupil edge 37. In this respect, the illumination setting 12a according to FIGS. 27 and 28 is comparable to that according to FIG. 11. In contrast thereto, the obscuration illumination pupil region 31 in the illumination pupil 12a according to FIGS. 27 and 28 is centred, and the envelope 32 has an approximately elliptical shape in the absolute pupil coordinates ρₓ, ρ_{y} (cf. FIG. 28) and an approximately stadium-shaped shape in the normalized pupil coordinates σₓ, σ_{y} (cf. FIG. 27).

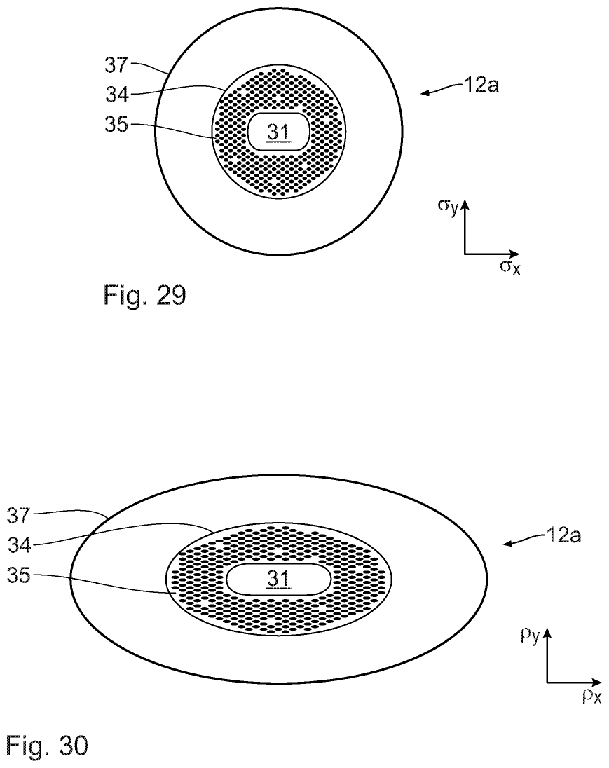

A further pupil embodiment, which can be used in place of the above-described illumination pupils that are each adapted to an exit pupil, is described hereinafter on the basis of FIGS. 29 and 30. Components and functions that correspond to those which were already explained above with reference to FIGS. 1 to 28, in particular with reference to FIGS. 7 to 28 and specifically with reference to FIGS. 25 and 28, bear the same reference signs in particular and will not be discussed in detail again.

The illumination pupil 12a according to FIGS. 29 and 30 is illuminated by the illumination light 3 between the envelope 32 of the obscuration illumination pupil region 31 on the one hand and the outer envelope 34 of the outer illumination pupil region 35. Apart from the fact that the pupil is not illuminated within the obscuration illumination pupil region 31 in the case of the illumination pupil 12a, the illumination pupil 12a according to FIGS. 29 and 30 is in this respect comparable to that according to FIG. 8.

In the case of the illumination pupil 12a according to FIGS. 29 and 30, the illumination pupil is not illuminated either within the envelope 32 or between the outer envelope 34 and the outer pupil edge 37.

With regard to the shape of the boundary of the envelope 32, the illumination pupil 12a according to FIGS. 29 and 30 is comparable to that according to FIGS. 27 and 28.

The outer envelope 34 has a circular shape in the illustration according to FIG. 29 in normalized pupil coordinates and is once again elliptical with a semimajor axis along the pupil coordinate ρₓ in absolute pupil coordinates (cf. FIG. 30).

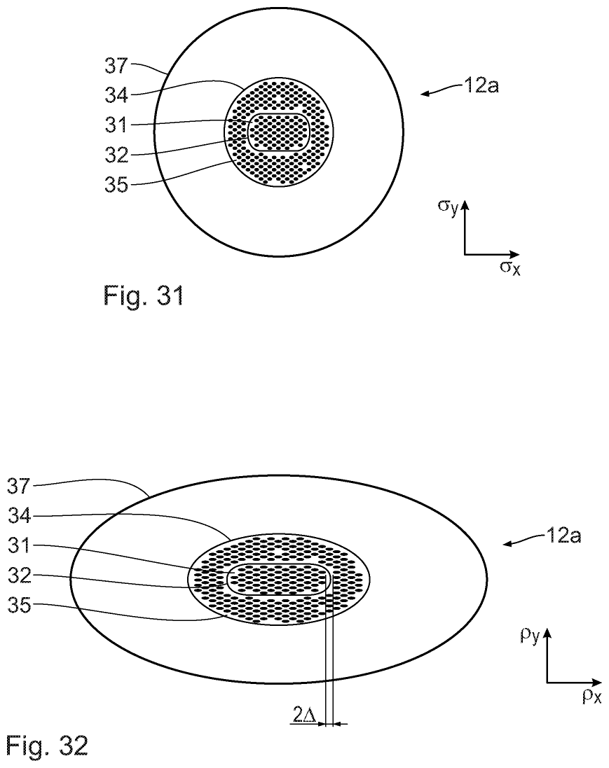

A further pupil embodiment, which can be used in place of the above-described illumination pupils that are each adapted to an exit pupil, is described hereinafter on the basis of FIGS. 31 and 32. Components and functions that correspond to those which were already explained above with reference to FIGS. 1 to 30, in particular with reference to FIGS. 7 to 30 and specifically with reference to FIGS. 25 and 30, bear the same reference signs in particular and will not be discussed in detail again.

In the case of the illumination pupil 12a according to FIGS. 31 and 32, both the obscuration illumination pupil region 31 and the outer illumination pupil region 35 between the envelope 32 and the outer envelope 34 are illuminated by the illumination light 3 by way of appropriate incidence locations 33ᵢ. The illumination pupil 12a is not impinged upon by the illumination light 3 in an illumination pupil surround around the envelope 32, which once again corresponds to a region of the exit pupil 36 adjacent to an edge of the associated obscuration exit pupil region 38. In this respect, the illumination pupil 12a according to FIGS. 31 and 32 corresponds to that according to FIG. 16.

A minimum distance 2 Δ between incidence locations 33ᵢ of the illumination light 3, firstly within the envelope 32 and secondly outside of the envelope 32, is also plotted in FIG. 32.

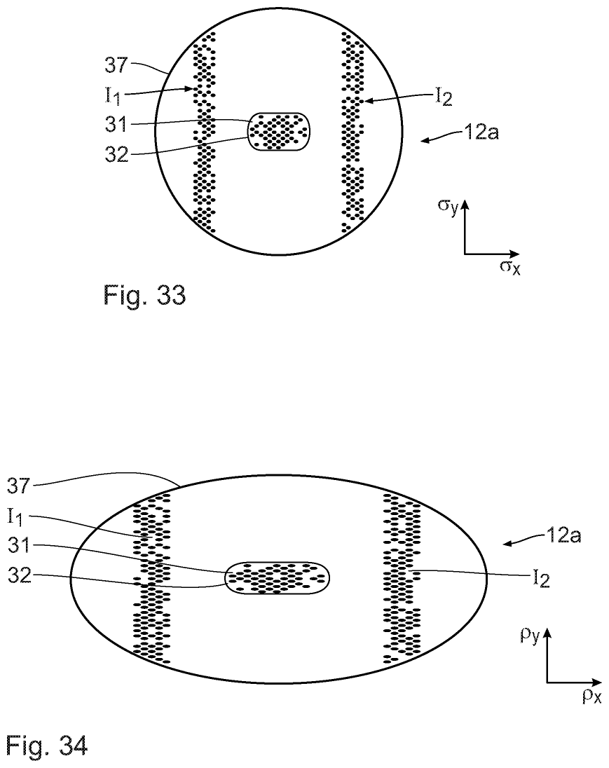

A further pupil embodiment, which can be used in place of the above-described illumination pupils that are each adapted to an exit pupil, is described hereinafter on the basis of FIGS. 33 and 34. Components and functions that correspond to those which were already explained above with reference to FIGS. 1 to 32, in particular with reference to FIGS. 7 to 32 and specifically with reference to FIGS. 25 and 32, bear the same reference signs in particular and will not be discussed in detail again.

The illumination pupil 12a according to FIGS. 33 and 34 is a superposition of firstly a dark field illumination pupil in the style of FIG. 25 and secondly an x-dipole illumination pupil with poles I₁, I₂ that represent an illumination in two σₓ/ρₓ-pupil coordinate regions in the form of pupil strips running along the pupil coordinate σ_{y}/ρ_{y}. In comparison with the illumination pupil 12a according to FIG. 14, the illumination poles I₁, I₂ have a continuous embodiment, i.e., they do not have an interruption at the location of the σ_{y}/ρ_{y}-pupil coordinates of the obscuration illumination pupil region 31.

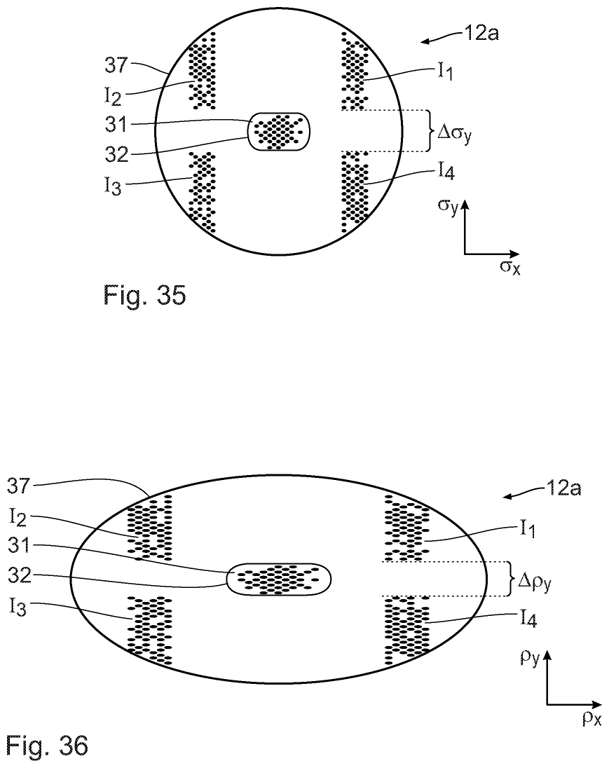

A further pupil embodiment, which can be used in place of the above-described illumination pupils that are each adapted to an exit pupil, is described hereinafter on the basis of FIGS. 35 and 36. Components and functions that correspond to those which were already explained above with reference to FIGS. 1 to 34, in particular with reference to FIGS. 7 to 34 and specifically with reference to FIGS. 25 and 34, bear the same reference signs in particular and will not be discussed in detail again.

The illumination pupil 12a according to FIGS. 35 and 36 corresponds to that according to FIG. 14, apart from the boundary shape of the envelope 32 and outer pupil edge 37, which are each elliptical in absolute pupil coordinates (cf. FIG. 36) and apart from the fact that the illumination pupil 12a according to FIGS. 35 and 36 is created using a second facet mirror 7 that is arranged in a pupil plane of the illumination optical unit 11.

The four illumination poles I₁ to I₄ of the illumination pupil 12a according to FIGS. 35 and 36 can be understood as a dipole illumination setting according to FIGS. 33 and 34 with an Δσ_{y}/Δρ_{y}-interruption of the σ_{y}/ρ_{y}-illumination strips along the pupil coordinates σ_{y}/ρ_{y} of the obscuration illumination pupil region 31.

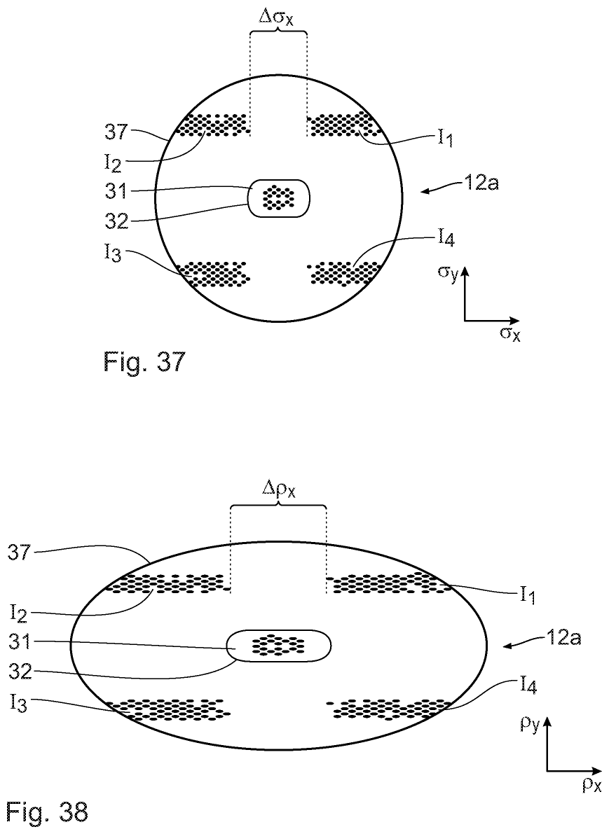

A further pupil embodiment, which can be used in place of the above-described illumination pupils that are each adapted to an exit pupil, is described hereinafter on the basis of FIGS. 37 and 38. Components and functions that correspond to those which were already explained above with reference to FIGS. 1 to 36, in particular with reference to FIGS. 7 to 36 and specifically with reference to FIGS. 25 and 36, bear the same reference signs in particular and will not be discussed in detail again.

In a manner comparable to the illumination optical unit 12a according to FIGS. 35 and 36, the illumination pupil 12a according to FIGS. 37 and 38 is a superposition of a dark field illumination pupil according to FIGS. 25 and 26 and a quadrupole illumination setting with four illumination poles I₁ to I₄.

Unlike the illumination pupil 12a according to FIGS. 35 and 36, the four poles I₁ to I₄ of the quadrupole illumination setting component of the illumination pupil 12a according to FIGS. 37 and 38 are formed within two pupil strips in specified σ_{y}/ρₓ-ranges that each extend along the σₓ/ρₓ-pupil coordinate and are each interrupted in Δσₓ/Δρₓ-pupil coordinate ranges that correspond to the σₓ/ρₓ-pupil coordinates of the obscuration illumination pupil region 31.

Unlike the illumination pupils 12a described above, for example the illumination pupils 12a according to FIGS. 9A/9B, 10, 12, 17 and 18, the illumination pupil 12a according to FIGS. 37 and 38 considers a diffraction of the illumination light 3 at structures of the reticle 12 along the pupil coordinate σ_{y}/ρ_{y}, which then represents the diffraction pupil coordinate. The illumination light cutouts between the poles I₁ and I₂ on the one hand and the poles I₃ and I₄ on the other hand ensure that imaging light 3 diffracted into the exit pupil 36 along the pupil coordinate σ_{y}/ρ_{y} is not undesirably diffracted into the obscuration illumination pupil region 31.

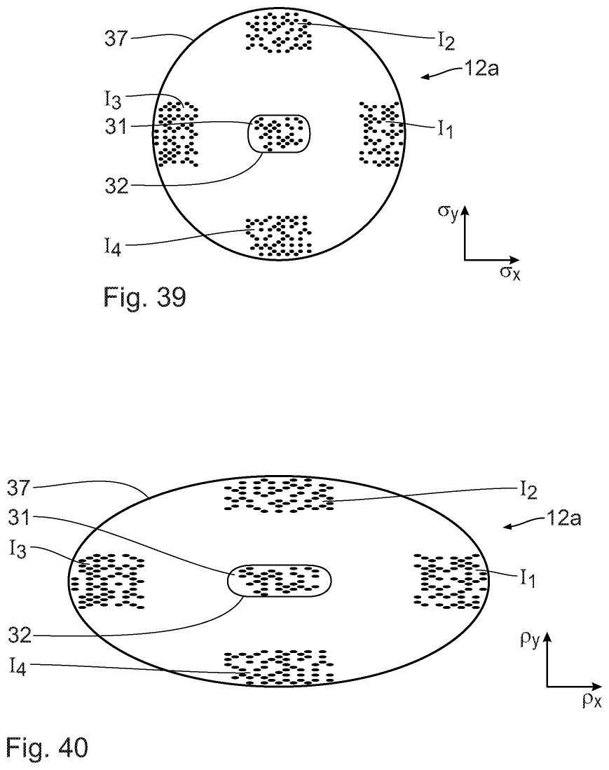

A further pupil embodiment, which can be used in place of the above-described illumination pupils that are each adapted to an exit pupil, is described hereinafter on the basis of FIGS. 39 and 40. Components and functions that correspond to those which were already explained above with reference to FIGS. 1 to 38, in particular with reference to FIGS. 7 to 38 and specifically with reference to FIGS. 25 and 38, bear the same reference signs in particular and will not be discussed in detail again.

In the illumination pupil 12a according to FIGS. 39 and 40, there is once again a central dark field illumination within the obscuration illumination pupil region 31 that corresponds to the illumination pupil 12a according to FIGS. 25 and 26. This dark field illumination is combined with a quadrupole illumination setting with illumination poles I₁ to I₄ in the positive σₓ/ρₓ-direction (I₁), in the positive σ_{y}/ρ_{y}-direction (I₂), in the negative σₓ/ρₓ-direction (I₃) and in the negative σ_{y}/ρ_{y}-direction (I₄). Unlike the case of the illumination pupils 12a with four illumination poles I₁ to I₄ as already described above, the four illumination poles I₁ to I₄ are thus not present within the four quadrants Q₁ to Q₄ in the illumination setting according to FIGS. 39 and 40, but in the direction of the pupil coordinates +/−σₓ and +/−σ_{y}. The illumination poles I₁ to I₄ are each arranged in the vicinity of the outer pupil edge 37, and thus lead to an illumination of the object field 8 with comparatively large illumination angles. Thus, in the range of normalized pupil coordinates, the illumination poles I₁ to I₄ are arranged at a σ-coordinate radius of between 0.8 and 1.

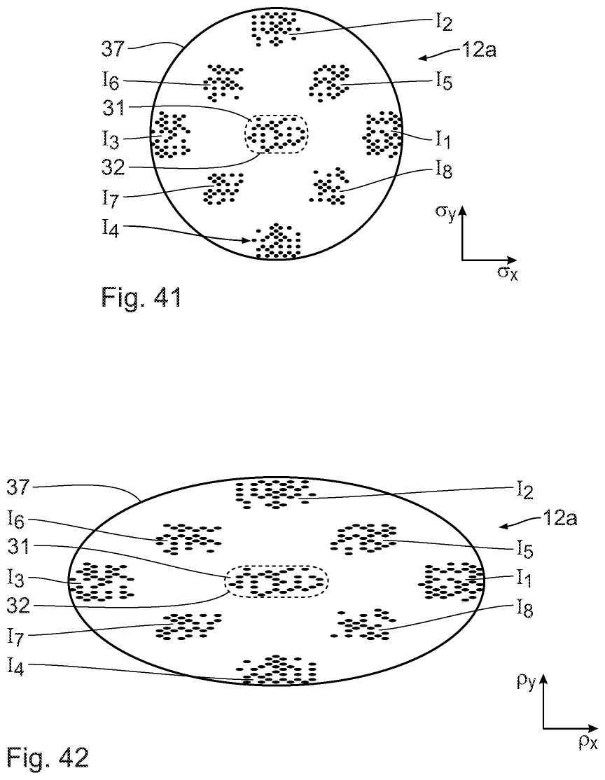

A further pupil embodiment, which can be used in place of the above-described illumination pupils that are each adapted to an exit pupil, is described hereinafter on the basis of FIGS. 41 and 42. Components and functions that correspond to those which were already explained above with reference to FIGS. 1 to 40, in particular with reference to FIGS. 7 to 40 and specifically with reference to FIGS. 25 and 40, bear the same reference signs in particular and will not be discussed in detail again.

The illumination pupil 12a according to FIGS. 41 and 42 once again contains an illumination of the obscuration illumination pupil region 31 like in the illumination pupil 12a according to FIGS. 25 and 26, i.e., a dark field illumination component. Additionally, eight further illumination poles I₁ to I₈ are present in the illumination pupil 12a according to FIGS. 41 and 42.

The illumination poles I₁ to I₄ are arranged in the style of the illumination poles I₁ to I₄ of the illumination pupil 12a according to FIGS. 39 and 40.

The additional illumination poles I₅ to I₈ are arranged in the region of middling illumination angles in the four quadrants of the illumination pupil 12a according to FIGS. 41 and 42, i.e., in the range of normalized pupil coordinates σₓ, σ_{y} with a radius around 0.5.

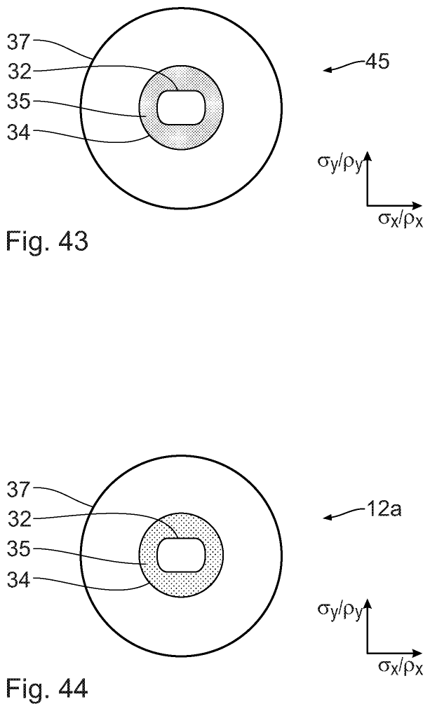

FIGS. 43 and 44 are used to describe a further illumination pupil 12a hereinafter, said illumination pupil being adapted to a corresponding exit pupil 36. Components and functions which were already explained above with reference to FIGS. 1 to 42 and in particular with reference to FIGS. 7 to 42 bear the same reference signs and will not be discussed in detail again.

FIG. 43 shows a target illumination pupil 45, which can be the result of a simulated calculation for optimizing the illumination of a reticle 12 structured in a specific manner. The target illumination pupil has an intensity distribution of the illumination light 3 which, in principle, corresponds to that of the illumination pupil 12a according to FIG. 29. The illumination light 3 is intended to illuminate the target illumination pupil 45 in a region between the envelope 32 of the obscuration illumination pupil region 31, which in turn is adapted to the obscuration exit pupil region of the exit pupil 36, and the outer envelope 34 of the outer illumination pupil region 35.

In the target illumination pupil 45, the envelope 32 of the obscuration illumination pupil region 31 has a boundary shape that is approximately stadium-shaped, with two straight lines that extend along the σₓ-pupil line and two curves that connect these two straight lines. The outer envelope 34 has a circular shape in pupil coordinates. A homogeneous and constant intensity distribution with the illumination light 3 is present between the inner envelope 32 and the outer envelope 34 in the case of the target illumination pupil 45.

The illumination pupil 12a according to FIG. 44 is depicted as a so-called x-field mean. Thus, the illumination pupil 12a is depicted in a manner averaged over all field heights x of the object field 8.

The target illumination pupil 45 according to FIG. 43 can be specified in the depicted form in normalized pupil coordinates, for example, according to FIG. 25, or else in absolute pupil coordinates, for example, in the style of FIG. 26. For example, the outer pupil edge 37 can be circular in normalized pupil coordinates as depicted in FIG. 43, but it might also be circular in absolute pupil coordinates.

FIG. 44 shows an illumination pupil 12a which represents an actual illumination pupil that approximates the target illumination pupil 45 according to FIG. 43 and which was created by the illumination optical unit 11 using the second facet mirror 7 at a distance from a pupil plane of the illumination optical unit 11 (cf. the exemplary illumination optical unit 11 according to FIG. 6). On account of the flexibility of the assignment and setting options for the individual mirrors ES and, in particular, of the grouping options for these individual mirrors ES of the two facet mirrors 6, 7 to form the transfer facet groups 21 and the illumination specification facet groups 25, the target illumination pupil 45 according to FIG. 43 can be reproduced practically perfectly in the x-field mean using the actual illumination pupil 12a according to FIG. 44. In particular, an illumination that is homogeneous and constant within the envelopes 32 and 34 or else optionally an approximation to a target intensity distribution can be achieved in the x-field mean, i.e., additionally to the y-field coordinate, integrated over the x-field coordinate.

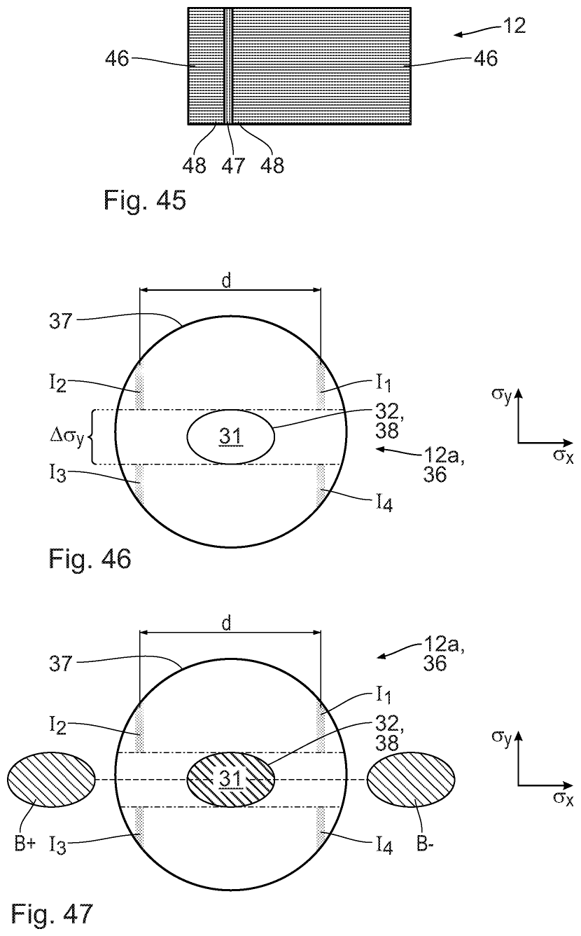

FIGS. 45 and 46 are used to explain a sequential and/or parallel, field-dependent use of various of the above-described illumination pupils 12a when imaging different regions of an exemplary reticle 12. Components and functions corresponding to those which have already been described above with reference to FIGS. 1 to 44 bear the same reference signs and will not be discussed in detail again.

The reticle 12 according to FIG. 45 has fine structure regions 46 that require a particularly high resolution of the projection exposure by use of the projection exposure apparatus 1. For example, the fine structures 46 can be very tightly spaced apart lines in the y-direction, i.e., vertical lines in FIG. 45.

In addition, in an x-field height region, the reticle 12 has coarse structures 47 with a typical structure extent greater than that of the fine structures 46. In the example under discussion, the coarse structures 47 are vertical lines once again, with a greater x-extent and periodicity in comparison with the fine structures 46.

The reticle 12 additionally contains transition regions 48 between the field height regions with the fine structures 46 and the field height regions with the coarse structures 47. Fine structures 46 can also be present on the reticle 12 in the transition regions 48. The transition regions 48 are spatially adjacent to the regions with the coarse structures 47.

FIG. 46 shows, by way of example, an adapted illumination pupil 12a for the fine structures 46. This illumination pupil 12a corresponds to the one explained above in the context of FIG. 10.

The illumination pupil 12a according to FIG. 46 is used for the x-field heights of the reticle in which the fine structures 46 are present. On account of the diffraction of the illumination light 3 at the fine structures 46 along the pupil coordinate σₓ, the space between the illumination poles I₁ and I₂ on the one hand and the illumination poles I₃ and I₄ on the other hand contains a diffraction offset or diffraction distance d, which corresponds to the σ_{y}-distance between these two poles I₁, I₂ on the one hand and I₃, I₄ on the other hand.

Moreover, the illumination optical unit 11 is set such that, at the x-field heights of the coarse structures 47 and of the transition regions 48, an illumination setting 12a, which differs from the illumination setting 12a according to FIG. 46 and which corresponds to the illumination setting 12a according to FIG. 14, is set. The coarse structures 47 and also the structures of the reticle in the transition region 48 are thus illuminated using the illumination setting 12a according to FIG. 47, including a dark field illumination within the obscuration illumination pupil region 31. Since the transition region 48 also contains only fine structures of the reticle 46, the illumination light radiated into the obscuration illumination pupil region 31 is diffracted at said structures to the pupil regions B+, B− outside of the outer pupil edge 37 in accordance with the diffraction offset d; these regions are blocked by the aperture stop of the projection optical unit 10 and therefore do not undesirably arrive on the wafer 19.

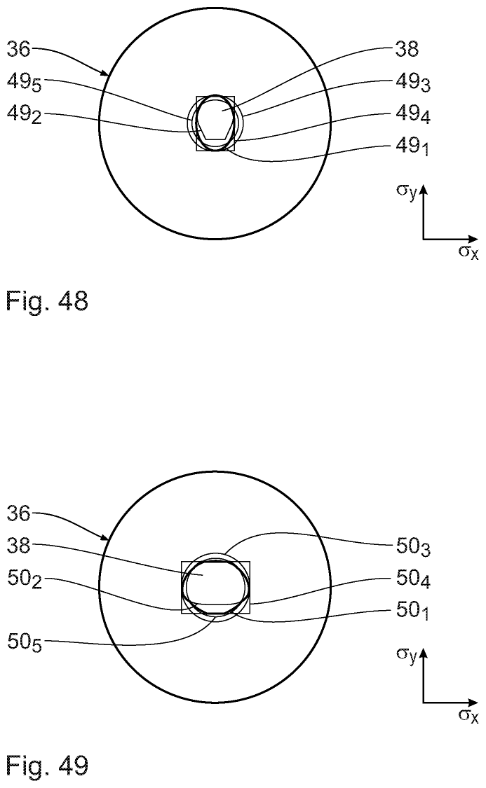

Various edge contours of an obscuration exit pupil region 38 are explained hereinafter on the basis of FIGS. 48 and 49; a corresponding illumination pupil 12a, in particular an obscuration illumination pupil region, can be adapted to said edge contours with the aid of the above-described techniques. Components and functions corresponding to those which have already been explained above with reference to FIGS. 1 to 47 bear the same reference signs and will not be discussed in detail again.

FIG. 48 shows variants of edge contours 49ᵢ of the obscuration exit pupil region 38. Within the scope of a method for calculating appropriate controls for the individual mirrors ES or facets 21, 25 of the illumination optical unit 11, these edge contours 49ᵢ, parameterized in terms of their shape, can be used to specify appropriate envelopes 32 of the obscuration illumination pupil region 31 of the respective illumination pupil 12a.

FIG. 48 shows edge contours 49ᵢ of the obscuration exit pupil region 38, which are assigned to a first design of the projection optical unit 10 of the projection exposure apparatus 1.

The edge contour 49₁ of the obscuration exit pupil region 38 has the shape of a vertical ellipse with a semimajor axis along the pupil coordinate σ_{y}.

The edge contour 49₂ has approximately a drop shape with a straight contour section located at the bottom in FIG. 48. This edge contour 49₂ represents a variant of a parameterization of an actual edge contour of the obscuration exit pupil region 38 of the first design of the projection optical unit 10, said variant neither being rotationally symmetric nor having multiple rotational symmetries.

The edge contour 49₃ represents a circular shape in which the edge contour 49₁ is inscribed, i.e., it represents the smallest circular diameter which completely accommodates the edge contour 49₁.

The edge contour 49₄ represents the smallest rectangle which accommodates the edge contour 49₁ therein, i.e., it has edge lengths along both the σₓ-coordinate and the σ_{y}-coordinate which correspond to the corresponding dimensions of the edge contour 49₁.

The edge contour 49₅ represents a circular shape, the area of which is exactly the same size as that of the edge contour 49₁.

Using the edge contours 49₁ to 49₅, it is possible to approximate an actual edge contour of the obscuration exit pupil region 38 of the projection optical unit 10 in parameterized fashion such that these edge contours 49₁ to 49₅ can be used to specify the envelope 32 of the obscuration illumination pupil region of an illumination pupil 12a adapted to this exit pupil 36.

FIG. 49 shows corresponding approximations of edge contours 50₁ to 50₅ to an actual edge contour of an obscuration exit pupil region 38 of a further design embodiment of the projection optical unit 10 of the projection exposure apparatus 1.

To an approximation, the edge contour 50₁ has the shape of a horizontal ellipse with a greater extent along the pupil coordinate σₓ.

The edge contour 50₂ once again represents a non-symmetric edge contour parameterization, which approximately has the shape of a spherical triangle.

The edge contour 50₃ once again represents a circular shape in which the edge contour 50₁ is inscribed.

The edge contour 50₄ represents a rectangle in which the edge contour 50₁ inscribed.

The edge contour 50₅ represents a circular shape with an area that equals that of the edge contour 50₁.

With regard to the parameterization boundary conditions, the edge contours 50₁ to 50₅ thus correspond to the edge contours 49₁ to 49₅, now applied to the further design of the projection optical unit 10, i.e., to an alternative edge contour design of the actual obscuration exit pupil region 38.

With regard to possible edge contour shapes of the envelope 32 of the obscuration illumination pupil region 31, which can be used to adapt to an arrangement, orientation and shape of an edge contour of the obscuration exit pupil region 38, the following boundary conditions may apply:

A mean radius of the envelope 32, expressed in normalized pupil coordinates σₓ, σ_{y}, can be in the range between 0.1 and 0.3 and in particular between 0.2 and 0.22.

A variation of the mean radius of the envelope 32 along the x-field height can be implemented within a tolerance of no more than 10%, no more than 5%, no more than 2% or else no more than 1%. This variation in the mean radius represents a field dependence of the obscuration illumination pupil region 31.

In normalized pupil coordinates, a σₓ-decentration and/or σ_{y}-decentration can be in the range between −0.2 and +0.2, in particular in the range between −0.1 and +0.1, and for example, in the range between −0.05 and +0.05 or else in the range between −0.005 and +0.005. This decentration of the envelope 32 can be field height-dependent, as explained above in the context of FIGS. 19 to 21, for example.

A deviation of the envelope 32 from an ideal circular shape, described for example, by the ratio of ellipse semi-axes lengths, can be in the range between 0.5 (ratio of the semi-axes lengths of 1:2) and 2 (ratio of the semi-axes lengths of 2:1).

In general, an edge contour of the obscuration exit pupil region 38 and/or an edge contour of the envelope 32 of the obscuration illumination pupil region 31 can be parameterized as follows, e.g., in the normalized pupil coordinates σₓ, σ_{y}, as explained using the example of the envelope 32:

$$r ( φ ) = {r}_{0} + 2 \cdot {\sum }_{n} ( {s}_{n} \cdot sin n φ + {c}_{n} \cdot cos n φ )$$

Here, r(φ) is the radius of the envelope 32, measured from a center of the entrance pupil 12a, for example from a centroid of area of the outer pupil edge 37 in the direction of the respective azimuth angle φ;
r₀ is a mean radius of the envelope 32;
sₙ and cₙ are coefficients of the respective Fourier contributions of order n.
s₁ for example, provides for a decentration of the envelope 32.
c₂ describes, for example, for small values, an approximately elliptical deviation of the shape of the envelope from an ideal circular shape.

To prepare the production of a microstructured component, there is initially a check with regard to the structure distribution and in particular the structure size distribution and structure orientation distribution that is present on the reticle 12. Moreover, the exit pupil 36 and in particular the shape of an envelope of the obscuration exit pupil region 38 are parameterized, as explained above. The result of the reticle verification and the parameterization of the exit pupil 36 is used to subsequently specify a target illumination pupil, for example, one of the above-described variants, and set the latter as illumination pupil 12a with the aid of the illumination optical unit 11 of the projection exposure apparatus 1.

In order to produce the microstructured component, in particular a highly integrated semiconductor component, for example a memory chip, with the aid of the projection exposure apparatus 1, the reticle 12 and the wafer 19 are subsequently provided. Subsequently, the structures on the reticle 12 are illuminated by the illumination light 3 using the appropriately set illumination optical unit 11 and projected onto a light-sensitive layer on the wafer 19 using the projection optical unit of the projection exposure apparatus 1. By developing the light-sensitive layer, a microstructure is then generated on the wafer 19 and the microstructured or nanostructured component is produced herefrom.

The produced component can be a microchip, in particular a memory chip.

What is claimed is:

1. An optical system for a projection exposure apparatus
having an illumination optical unit for guiding illumination and imaging light from a light source to an object field, in which an object to be imaged is arrangeable,
having an imaging optical unit for imaging the object field into an image field, in which a substrate to be exposed is arrangeable, the imaging optical unit comprising an exit pupil having at least one obscuration exit pupil region located within an outer pupil edge,
the illumination optical unit being embodied in such a way that an illumination angle distribution of an illumination of the object field using the illumination and imaging light arises and is describable by way of an illumination pupil, the illumination pupil region of which impinged upon by illumination light being adapted to the obscuration exit pupil region of the imaging optical unit,
the obscuration exit pupil region of the imaging optical unit having a non-centric geometric centroid.

2. An optical system for a projection exposure apparatus
having an illumination optical unit for guiding illumination and imaging light from a light source to an object field, in which an object to be imaged is arrangeable,
having an imaging optical unit for imaging the object field into an image field, in which a substrate to be exposed is arrangeable, the imaging optical unit comprising an exit pupil having at least one obscuration exit pupil region located within an outer pupil edge,
the illumination optical unit being embodied in such a way that an illumination angle distribution of an illumination of the object field using the illumination and imaging light arises and is describable by way of an illumination pupil, the illumination pupil region of which impinged upon by illumination light being adapted to the obscuration exit pupil region of the imaging optical unit,
the illumination optical unit being embodied in such a way that an illumination angle distribution arises in the object field and is describable by way of an illumination pupil with an obscuration illumination pupil region, the envelope of which, in
pupil coordinates (σₓ, σ_{y}) normalized with respect to the outer pupil edge and/or
in absolute pupil coordinates (ρₓ, ρ_{y}),
deviates from a circular shape.

3. The optical system according to claim 1, forming such an embodiment that the illumination pupil is not impinged upon by the illumination light in at least one illumination pupil region which corresponds to the obscuration exit pupil region.

4. The optical system according to claim 1, embodied for the illumination of an object structure of the object which leads to a diffraction of the imaging light downstream of the object along a diffraction pupil coordinate (σₓ, σ_{y}) of the exit pupil, the illumination pupil not being impinged upon by the illumination light in an illumination pupil coordinate range (Δσ_{y}) of a cross diffraction pupil coordinate (σ_{y}) perpendicular to the diffraction pupil coordinate (σₓ), the illumination pupil coordinate range corresponding to the extent of the obscuration exit pupil region along this cross diffraction pupil coordinate (σ_{y}).

5. The optical system according to claim 1, wherein the illumination pupil comprises an obscuration illumination pupil region in which the illumination pupil is not impinged upon by the illumination light, with illumination angles assigned to the obscuration illumination pupil region corresponding with at least partial overlap to imaging beam angles of zeroth order of diffraction of the obscuration exit pupil region and with illumination pupil regions in which the illumination pupil is impinged upon by the illumination light being arranged directly adjacent to the obscuration illumination pupil region.

6. The optical system according to claim 1, forming such an embodiment that the illumination pupil with an obscuration illumination pupil region which corresponds to the obscuration exit pupil region is impinged upon by the illumination light.

7. The optical system according to claim 6, forming such an embodiment that the illumination pupil is impinged upon by the illumination light in an illumination pupil region containing the obscuration illumination pupil region.

8. The optical system according to claim 7, wherein the illumination pupil region is not impinged upon by the illumination light in an illumination pupil surround (Δ) which corresponds to a region of the exit pupil adjacent to an edge of the obscuration exit pupil region.

9. The optical system according to claim 6, forming such an embodiment that the illumination pupil is only impinged upon by the illumination light in an obscuration illumination pupil region which corresponds to the obscuration exit pupil region.

10. The optical system according to claim 9, wherein the obscuration exit pupil region comprises at least one subsection in which the obscuration illumination pupil region is not impinged upon by the illumination light.

11. The optical system according to claim 1, comprising an illumination pupil that is field-dependent by way of the object field.

12. The optical system according to claim 1, wherein the imaging optical unit is embodied in such a way that the exit pupil of the imaging optical unit is field-dependent by way of the object field, with the illumination optical unit being embodied in such a way that the illumination pupil has a field dependence corresponding to that of the exit pupil.

13. The optical system according to claim 1, wherein an outer edge contour of the obscuration exit pupil region has a shape that can be described by use of at least one of the following parameters:
mean radius of the edge contour in the range between 0.1 and 0.3 of a normalized pupil coordinate radius,
decentration of the edge contour in the range between 0.0025 and 0.05 of the normalized pupil coordinate radius, or
mean deviation of the edge contour from a circular shape in the range between 0.01 and 0.2 of the normalized pupil coordinate radius.

14. The optical system according to claim 1, wherein the illumination optical unit comprises:
a field facet mirror arranged in a field plane of the illumination optical unit, and
a pupil facet mirror arranged in a pupil plane of the illumination optical unit.

15. The optical system according to claim 1, wherein transfer facets of a transfer facet mirror of the illumination optical unit and/or illumination specification facets of an illumination specification facet mirror of the illumination optical unit are subdivided into a plurality of individual mirrors that are independently tiltable for the purpose of specifying the illumination pupil.

16. The optical system according to claim 1, comprising a light source for the illumination and imaging light.

17. The optical system according to claim 1, wherein, in normalized pupil coordinates, a decentration of an edge contour of the obscuration exit pupil region is in a range between −0.2 and +0.2, in particular wherein the decentration of the edge contour of the obscuration exit pupil region is in a range between −0.05 and +0.05.

18. The optical system according to claim 1, wherein a geometrical center of gravity of the outer pupil edge is arranged within the obscuration exit pupil region.

19. A projection exposure apparatus having an optical system according to claim 1.

20. A method for specifying an illumination pupil of an illumination optical unit for illuminating an object field, in which an object to be imaged is arrangeable, with illumination light, including the following steps:
analyzing a diffraction behavior of at least one object structure of the object,
detecting a position of an obscuration exit pupil region in an exit pupil of an imaging optical unit for imaging the object, and
adapting the illumination pupil such that this results in an optical system according to claim 1.

21. The method according to claim 20, wherein this results in a field dependence of the illumination pupil that is adapted to the exit pupil and/or to the object structure.

22. A method for producing a microstructured component, including the following method steps:
carrying out the method according to claim 20,
providing the object with the analyzed diffraction behavior, in the form of a reticle,
providing a wafer having a coating that is sensitive to the illumination light,
projecting at least one section of the reticle onto the wafer with the aid of the projection exposure apparatus having an optical system, using the optical system with the appropriately adapted illumination pupil,
wherein the optical system comprises:
the illumination optical unit for guiding illumination and imaging light from a light source to the object field,
the imaging optical unit for imaging the object field into an image field, in which a substrate to be exposed is arrangeable, the imaging optical unit comprising an exit pupil having at least one obscuration exit pupil region located within an outer pupil edge,
wherein an illumination angle distribution of an illumination of the object field using the illumination and imaging light arises and is describable by way of the illumination pupil, the illumination pupil region of which impinged upon by illumination light being adapted to the obscuration exit pupil region of the imaging optical unit,
wherein the obscuration exit pupil region of the imaging optical unit has a non-centric geometric centroid; and
developing the light-sensitive layer exposed with the illumination light on the wafer.

23. A component, produced according to a method as claimed in claim 22.
